(19) United States
(12) Patent Application Publication
(10) Pub. No.: US 2019/0221728 A1
(43) Pub. Date: Jul. 18, 2019

(54) LIGHT-EMITTING DEVICE AND THE MANUFACTURING METHOD THEREOF

(71) Applicant: EPISTAR CORPORATION, Hsinchu (TW)

(72) Inventors: Jen-Chieh YU, Hsinchu (TW); Yih-Hua RENN, Hsinchu (TW); Hsin-Mao LIU, Hsinchu (TW); Lung-Kuan LAI, Hsinchu (TW); Ching-Tai CHENG, Hsinchu (TW)

(21) Appl. No.: 16/250,774

(22) Filed: Jan. 17, 2019

(30) Foreign Application Priority Data
Jan. 17, 2018 (TW) 107101749
Dec. 19, 2018 (TW) 107146004

(51) Int. Cl. H01L 33/50; H01L 33/58; H01L 25/13

(52) U.S. Cl. CPC H01L 33/507; H01L 25/13; H01L 33/58

(57) ABSTRACT

An embodiment of present disclosure discloses a light-emitting device which includes a first light-emitting unit, a second light-emitting unit, a first optic structure, a second optic structure, a first light-transmitting structure, a second light-transmitting structure, and a light-blocking structure. The first optic structure covers a top surface and a side surface of the first light-emitting unit, the second optic structure covers a top surface and a side surface of the second light-emitting unit. The first light-transmitting structure covers the first optic structure. The second light-transmitting structure covers the second optic structure. The light-blocking structure surrounds the first light-emitting unit and the second light-emitting unit, and covers the side surfaces of the first optic structure, the second optic structure, the first light-transmitting structure and the second light-transmitting structure.

### CROSS-REFERENCE TO RELATED APPLICATIONS

This application claims priority to and the benefit of Taiwan Patent Application No. 107101749 filed on Jan. 17, 2018, and Taiwan Patent Application No. 107146004 filed on Dec. 19, 2018, and the content of which are incorporated by reference in their entirety.

### TECHNICAL FIELD

The present disclosure relates to a light-emitting device, particularly to a light-emitting device having a wavelength-converting material.

### DESCRIPTION OF BACKGROUND ART

Light-emitting diode (LED) has the characteristics of low energy consumption, long life-time, small volume, fast response and stable optical output. LED gradually replaces the traditional illumination sources and is used in various lighting devices.

In various illumination applications of LED, phosphor powder is often used in combination with LED to emit various color lights. The characteristics of the phosphor powder, such as the concentration and material, can change the lighting properties of LED. The LED coverage of the phosphor powder also affects the overall illumination angle and efficiency.

### SUMMARY OF THE DISCLOSURE

A light-emitting device disclosed in the embodiments in accordance with the present disclosure comprises a first light-emitting unit having a first top surface, a first side surface and a first bottom surface. A second light-emitting unit has a second top surface, a second side surface and a second bottom surface. A first pair of conductive electrodes is disposed on the first bottom surface. A second pair of conductive electrodes is disposed on the second bottom surface. A first optic structure has a first outer side surface. The first optic structure covers the first top surface and the first side surface. A second optic structure has a second outer side surface. The second optic structure covers the second top surface and the second side surface. A first light-transmitting structure has a third outer side surface and covers the first optic structure. A second light-transmitting structure has a fourth outer side surface and covers the second optic structure. A light-blocking structure surrounds the first light-emitting unit and the second light-emitting unit. The light-blocking structure covers the first outer side surface, the second outer side surface, the third outer side surface and the fourth outer side surface.

### BRIEF DESCRIPTION OF THE DRAWINGS

FIGS. 1A to 1C show the cross-sectional view, top view and bottom view of a light-emitting device in accordance with an embodiment of the present disclosure.

FIGS. 2A to 2B show the cross-sectional view and bottom view of a light-emitting device in accordance with an embodiment of the present disclosure.

FIGS. 3A to 3B show the cross-sectional view and bottom view of a light-emitting device in accordance with an embodiment of the present disclosure.

FIGS. 4A to 4C show the top views of a light-emitting device in accordance with other embodiments of the present disclosure.

FIG. 5 is a comparison table of luminous fluxes of different light-emitting devices.

FIGS. 6A to 6E show the diagrams of manufacturing process of a light-emitting device in accordance with an embodiment of the present disclosure.

FIGS. 7A to 7C show the top views of the combinations of a light-emitting device and a lens in accordance with the present disclosure.

FIGS. 8A to 8C show the light uniformity measurement diagrams of different light-emitting devices disclosed in FIGS. 7A to 7C.

FIG. 9A shows a diagram of the measurement method for light uniformity.

FIG. 9B shows an illuminance distribution diagram in the measurement screen.

FIG. 10 shows a diagram of a backlight module using the light-emitting devices disclosed in an embodiment of the present disclosure.

FIGS. 11A to 11C show the cross-sectional views of light-emitting devices in accordance with an embodiment of the present disclosure.

FIG. 11D shows a top view of a light-emitting device in accordance with an embodiment of the present disclosure.

FIGS. 12A to 12E show the diagrams of manufacturing process of a light-emitting device in accordance with an embodiment of the present disclosure.

FIGS. 13A to 13C show the cross-sectional view, top view and bottom view of a light-emitting device in accordance with another embodiment of the present disclosure.

FIG. 13D shows a bottom view of a light-emitting device in accordance with another embodiment of the present disclosure.

FIGS. 14A to 14F show the diagrams of manufacturing process of a light-emitting device in accordance with an embodiment of the present disclosure.

FIG. 15A shows a cross-sectional view of a light-emitting device in accordance with another embodiment of the present disclosure.

FIG. 15B shows a cross-sectional view of a light-emitting device in accordance with another embodiment of the present disclosure.

FIG. 15C shows a cross-sectional view of a light-emitting device in accordance with another embodiment of the present disclosure.

FIGS. 16A to 16B show the cross-sectional view and perspective view of a light-emitting device in accordance with another embodiment of the present disclosure.

FIGS. 16C to 16D show the cross-sectional view and perspective view of a light-emitting device in accordance with another embodiment of the present disclosure.

FIGS. 17A to 17C show the cross-sectional view, top view and bottom view of a light-emitting device in accordance with another embodiment of the present disclosure.

FIGS. 18A to 18C show the cross-sectional view, top view and bottom view of a light-emitting device in accordance with another embodiment of the present disclosure.

FIGS. 19A to 19C show the cross-sectional view, top view and bottom view of a light-emitting device in accordance with another embodiment of the present disclosure.

FIGS. 20A to 20C show the top views of a light-emitting device in accordance with another embodiment of the present disclosure.

FIGS. 21A to 21B show the top views of a light-emitting device in accordance with another embodiment of the present disclosure.

FIG. 22 shows a top view of a light-emitting device in accordance with an embodiment of the present disclosure.

FIGS. 23A to 23F show the diagrams of manufacturing process of a light-emitting device in accordance with an embodiment of the present disclosure.

FIGS. 24A to 24G show the diagrams of manufacturing process of a light-emitting device in accordance with an embodiment of the present disclosure.

FIGS. 25A to 25C show the cross-sectional view, top view, and bottom view of a light-emitting device in accordance with an embodiment of the present disclosure.

FIGS. 26A to 26B show the cross-sectional view and bottom view of a light-emitting device in accordance with an embodiment of the present disclosure.

FIGS. 27A to 27C show the diagrams of manufacturing process of a light-emitting device in accordance with an embodiment of the present disclosure.

FIGS. 28A to 28D show the diagrams of manufacturing process of a light-emitting device in accordance with an embodiment of the present disclosure.

### DETAILED DESCRIPTION OF THE PRESENT DISCLOSURE

The following embodiments are intended to illustrate the concept of the present disclosure. In the drawings or the description, the similar or the same parts are using the same labels. The shape, thickness or height of the elements can be expanded or shrunk within a reasonable range in the drawings. The examples of the present disclosure are only used to illustrate the present disclosure and not to limit the scope of the present disclosure. Any obvious modifications or alterations of the present disclosure are possible without departing from the spirit and scope of the present disclosure.

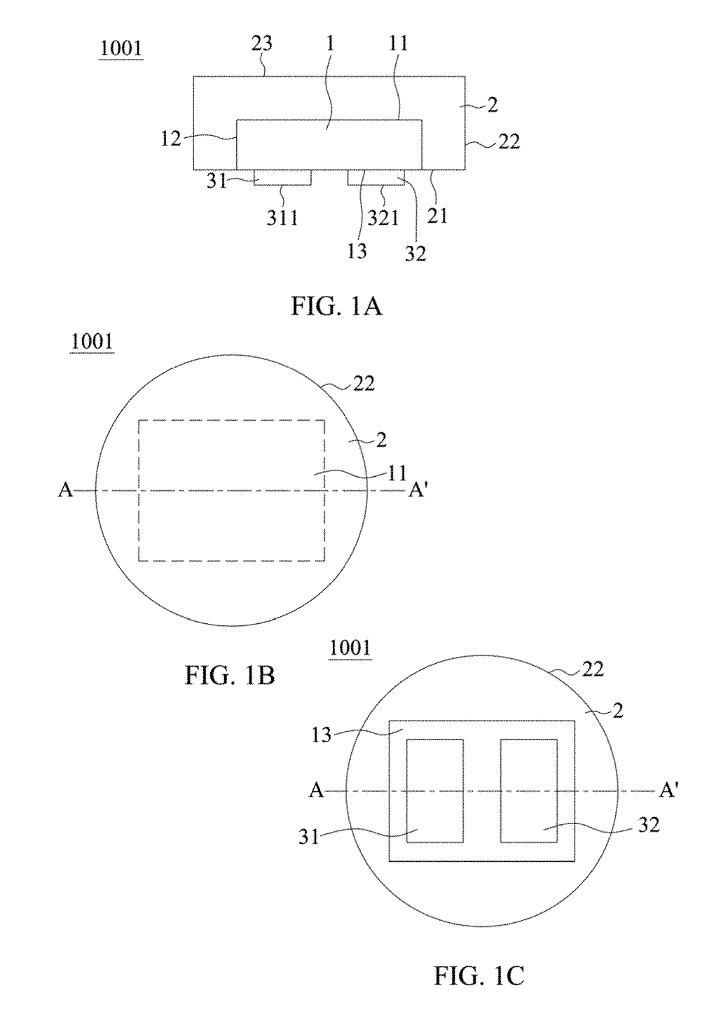

FIG. 1A shows a cross-sectional view of a light-emitting device 1001 in accordance with an embodiment of the present disclosure. FIG. 1B shows a top view of a light-emitting device 1001 in accordance with an embodiment of the present disclosure. FIG. 1C shows a bottom view of a light-emitting device1001 in accordance with an embodiment of the present disclosure. FIG. 1A is a cross-sectional view taken along line AA′ of FIG. 1B and FIG. 1C. The light-emitting device 1001 includes a light-emitting unit 1, a light-transmitting structure 2, and a pair of conductive electrodes 31, 32. Referring to FIG. 1A, the light-emitting unit 1 includes a top surface 11, a bottom surface 13 opposite to the top surface 11, and a plurality of side surfaces 12 connecting the top surface 11 and the bottom surface 13. The light-transmitting structure 2 covers the top surface 11 of the light-emitting unit 1 and the plurality of side surfaces 12. Therefore, the light emitted by the light-emitting unit 1 exits the light-emitting device 1001 through the outer side surfaces 22 and the top surface 23 of the light-transmitting structure 2. The pair of conductive electrodes 31, 32 are located on the bottom surface 13 of the light-emitting unit 1 for electrical connection with an external power supply system. The pair of conductive electrodes 31, 32 may protrude from the light-transmitting structure 2. In other words, the bottom surfaces 311, 321 of the pair of conductive electrodes 31, 32 are not flush with the bottom surface 13 of the light-emitting unit 1 and the bottom surface 21 of the light-transmitting structure 2. The bottom surface 13 of the light-emitting unit 1 is substantially flush with the bottom surface 21 of the light-transmitting structure 2. Referring to FIG. 1B, the top surface 11 of the light-emitting unit 1 has a rectangular shape from a top view, and the light-transmitting structure 2 covering around the light-emitting unit 1 has a circular shape from a top view. Referring to FIG. 1C, the light-transmitting structure 2 does not cover the bottom surface 13 of the light-emitting unit 1, and the pair of conductive electrodes 31, 32 are located on a portion of the bottom surface 13 of the light-emitting unit 1. Therefore, a part of the light of the light-emitting unit 1 is emitted from the bottom surface 13 without passing through the light-transmitting structure 2. The shapes of the pair of conductive electrodes 31, 32 are merely exemplified, and the shape, size, and arrangement of the pair of conductive electrodes are not limited thereto.

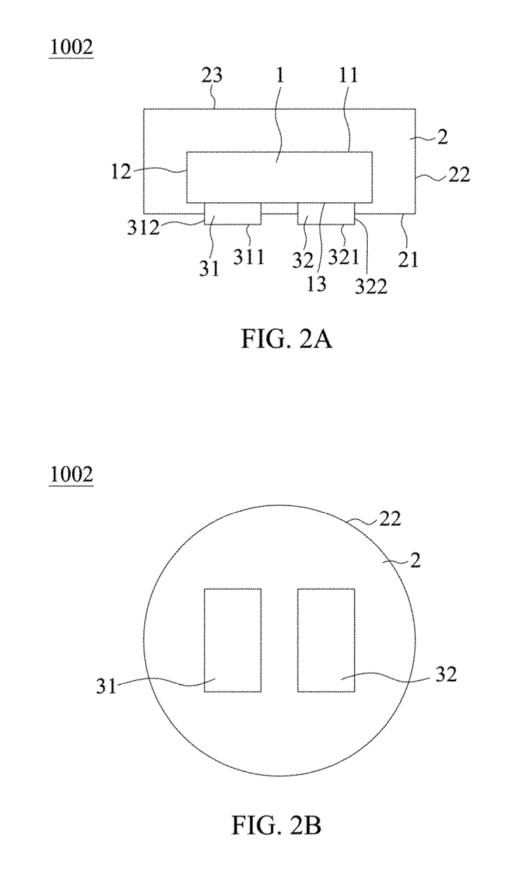

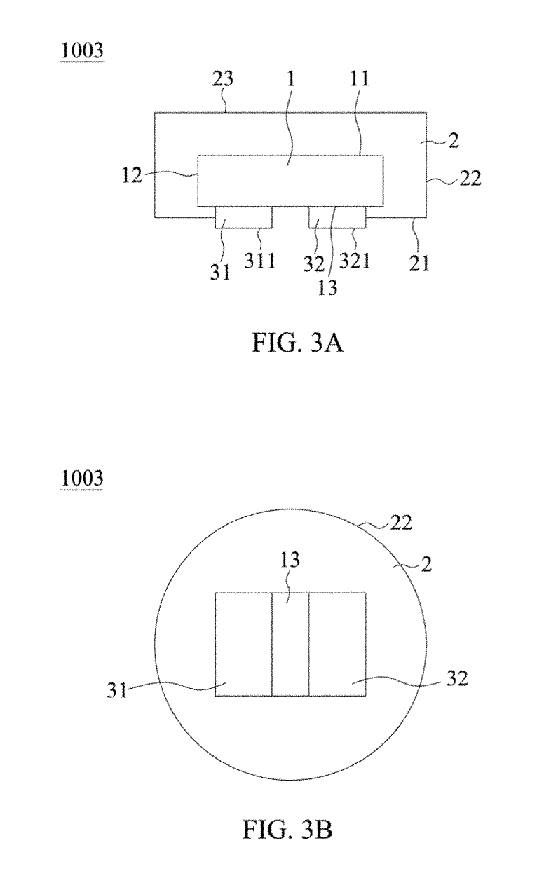

In another embodiment, the light-transmitting structure 2 substantially covers the entire bottom surface of the light-emitting unit 1 where the pair of conductive electrodes 31, 32 are not formed, as shown in FIG. 2A. Referring to FIG. 2A, the light-transmitting structure 2 of the light-emitting device 1002 covers a portion of the outer side surface 312 of the conductive electrode 31 and a portion of the outer side surface 322 of the conductive electrode 32. Moreover, the light-transmitting structure 2 fills the region between the pair of conductive electrodes 31, 32. It is to be noted that the bottom surfaces 311, 321 of the pair of conductive electrodes 31, 32 protrude from the light-transmitting structure 2 and are not flush with the bottom surface 21. Therefore, the bottom surface of the light-emitting unit 1 can be protected by the coverage of the light-transmitting structure 2. FIG. 2B is a bottom view of the light-emitting device 1002. The light-transmitting structure 2 covers the whole bottom surface 13 of the light-emitting unit 1 and exposes the pair of conductive electrodes 31, 32. In another embodiment, the light-transmitting structure 2 covers a portion of the bottom surface of the light-emitting unit 1, as shown in FIG. 3A. Referring to FIG. 3A, the bottom surface of the light-emitting unit 1 of the light-emitting device 1003 between the pair of conductive electrodes 31, 32 is not covered by the light-transmitting structure 2. The light-transmitting structure 2 of the light-emitting device 1003 covers a portion of the outer side surface 312 of the conductive electrode 31 and a portion of the outer side surface 322 of the conductive electrode 32. FIG. 3B is a bottom view of the light-emitting device 1003. The light-transmitting structure 2 covers a portion of the bottom surface of the light-emitting unit 1 and exposes the bottom surface of the light-emitting unit 1 between the pair of conductive electrodes 31, 32. Referring to FIG. 3B, the exposed area of the center of the light-transmitting structure 2 is substantially square, and an outer side of the bottom surface 13 of the light-emitting unit 1 is substantially flush with the outer sides of the pair of conductive electrodes 31, 32. In another embodiment, the light-transmitting structure 2 cover a portion of the bottom surface 13, such as the upper and lower edges of the bottom surface 13. Therefore, from the bottom view, the upper and lower sides of the exposed bottom surface 13 of the light-emitting unit 1 are retracted from the outer sides of the pair of conductive electrodes 31, 32.

The material of the pair of conductive electrodes 31, 32 may be metal such as gold (Au), silver (Ag), copper (Cu), chromium (Cr), aluminum (Al), platinum (Pt), nickel (Ni), titanium (Ti), tin (Sn), or an alloy thereof, or a combination thereof. The material of the light-transmitting structure 2 may include silicone, epoxy, polyimidine (PI), benzocyclobutene (BCB), perfluorocyclobutane (PFCB), SU8, acrylic resin, polymethyl methacrylate (PMMA), polyethylene terephthalate (PET), polycarbonate (PC), polyetherimide. In an embodiment, the light-transmitting structure 2 may comprise a wavelength-converting material (for example, phosphor powder, dye or quantum dot luminous material). The wavelength-converting material may comprise one or two or more kinds of inorganic phosphor, organic fluorescent colorant, semiconductor, or a combination thereof. The inorganic phosphor material has particle size of 5 μm to 100 μm and includes, but is not limited to, yellow-green phosphor powder and red phosphor powder. The composition of the yellow-green phosphor is, for example, an aluminum oxide (for example, yttrium aluminum garnet (YAG) or yttrium aluminum garnet (TAG)), silicate, vanadate, alkaline earth metal selenide, or metal nitride. The composition of the red phosphor is, for example, fluoride (K₂TiF₆: Mn⁴⁺, K₂SiF₆: Mn⁴⁺), citrate, vanadate, alkaline earth metal sulfide (CaS), metal oxynitride, or a mixture of tungsten molybdate. The semiconductor material includes semiconductor material of nano-sized crystal, such as quantum-dot luminous material. The quantum dot luminous material may be ZnS, ZnSe, ZnTe, ZnO, CdS, CdSe, CdTe, GaN, GaP, GaSe, GaSb, GaAs, AlN, AlP, AlGaAs, InP, InAs, PbS, PbSe, SbTe, ZnCdSeS, CuInS, CsPbCl₃, CsPbBr₃, and CsPbI₃.

The light-emitting unit 1 is a semiconductor light-emitting device capable of emitting non-coherent light, and includes a carrier, a first type semiconductor layer, an active layer, and a second type semiconductor layer. The first type semiconductor layer and the second type semiconductor layer are, for example, a cladding layer or a confinement layer, and can respectively provide electrons and holes for electrons and holes to be combined in the active layer to emit light. The first type semiconductor layer, the active layer, and the second type semiconductor layer may comprise a III-V semiconductor material, such as AlₓIn_{y}Ga_{(1-x-y)}N or AlₓIn_{y}Ga_{(1-x-y)}P, wherein 0≤x, y≤1; (x+y)≤1. Depending on the material of the active layer, the light-emitting unit 1 can emit a red light with a peak wavelength of between 610 nm and 650 nm, a green light with a peak wavelength of between 530 nm and 570 nm, and a blue light with a peak wavelength of between 450 nm and 490 nm, or a near-ultraviolet light with a peak wavelength of between 405 nm and 450 nm, or a ultraviolet light with a peak wavelength of between 280 nm and 400 nm. The carrier can be used as a growth substrate of the first type semiconductor layer, the active layer, and the second type semiconductor layer, or be a support for the first type semiconductor layer, the active layer, and the second type after removing the growth substrate. The material of the substrate includes, but is not limited to, Ge, GaAs, InP, sapphire, SiC, Si, LiAlO₂, ZnO, GaN, AlN, metal, glass, composite material, diamond, CVD diamond, and diamond-like carbon (DLC).

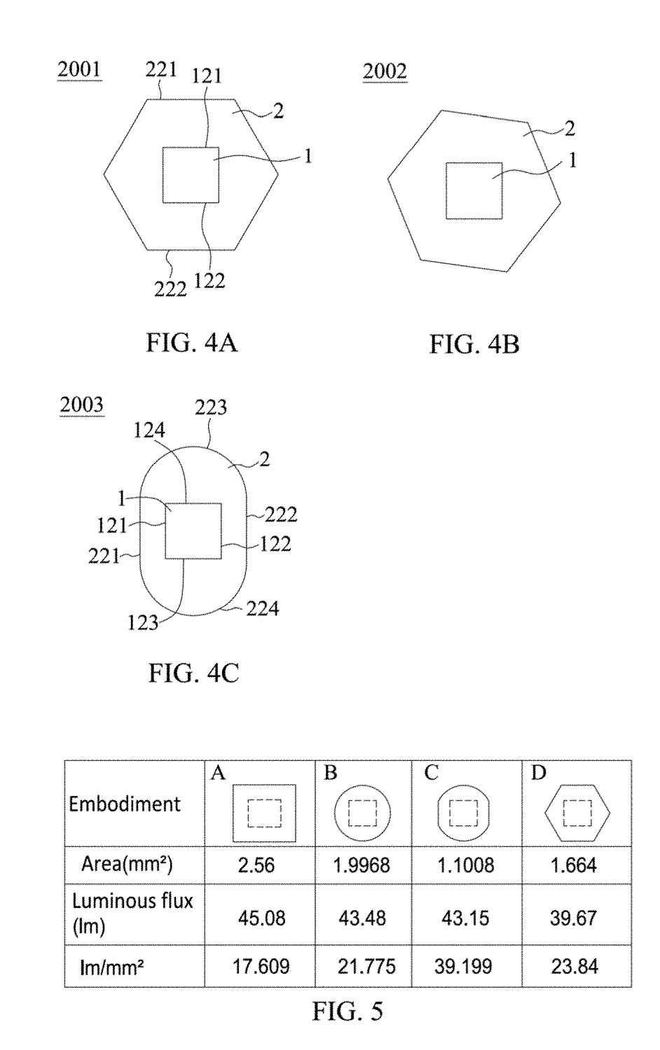

In another embodiment, the light-emitting unit 1 has a rectangular shape from the top view, and the light-transmitting structure 2 has a non-circular shape. The shape of the light-transmitting structure 2 is different from that of the light-emitting unit 1, as shown in FIGS. 4A to 4C. FIG. 4A shows a top view of a light-emitting device 2001 in an embodiment of the present disclosure. The light-transmitting structure 2 of the light-emitting device 2001 has a hexagonal shape in the top view. The light-transmitting structure 2 has two outer side surfaces which are respectively parallel to the two outer side surfaces of the light-emitting unit 1. In detail, referring to FIG. 4A, the light-transmitting structure 2 has a pair of outer side surfaces 221, 222 which are facing and parallel to each other, and the light-emitting unit 1 has a pair of outer side surfaces 121, 122 which are facing and parallel to each other. The outer side surface 221 of the light-transmitting structure 2 is facing and parallel to the outer side surface 121 of the light-emitting unit 1, and the outer side surface 222 of the light-transmitting structure 2 is facing and parallel to the outer side surface 122 of the light-emitting unit 1. FIG. 4B shows a top view of a light-emitting device 2002 in another embodiment of the present disclosure. The light-transmitting structure 2 of the light-emitting device 2002 is similar to FIG. 4A, and has a hexagonal shape in the top view. Each outer side of the light-transmitting structure 2 is not parallel to the outer side of the light-emitting unit 1. FIG. 4C shows a top view of a light-emitting device 2003 in another embodiment of the present disclosure. The light-transmitting structure 2 of the light-emitting device 2003 has a non-rectangular shape different from the light-emitting unit 1 in the top view. Referring to FIG. 4C, the light-transmitting structure 2 has two outer side surfaces 221, 222 which are facing and parallel to each other, and two curved outer side surfaces 223, 224 which connect with the outer side surfaces 221, 222. The outer side surfaces 121,122 of the light-emitting unit 1 face each other and are parallel to each other, and the outer side surfaces 123, 124 face each other and are parallel to each other. The outer side surface 221 of the light-transmitting structure 2 is facing and parallel to the outer side surface 121 of the light-emitting unit 1, and the outer side surface 222 of the light-transmitting structure 2 is facing and parallel to the outer side surface 122 of the light-emitting unit 1. The curved outer side surface 223 of the light-transmitting structure 2 is facing but not parallel to the outer side surface 124 of the light-emitting unit 1. The curved outer side surface 224 of the light-transmitting structure 2 is facing but not parallel to the outer side surface 123 of the light-emitting unit 1. In another embodiment, from the top view, the light-emitting unit 1 is rectangular, and the shape of the light-emitting device is square, that is, the shape of the light-transmitting structure 2 is square and different from that of the light-emitting unit 1. Or the shape of the light-emitting unit 1 is square, and the shape of the light-emitting device is rectangular so the shape of the light-transmitting structure 2 is rectangular.

FIG. 5 shows a luminous flux comparison table of four kinds of light-emitting devices with different light-transmitting structure shape. The light-emitting devices of types A to D have a light-emitting unit with the same photoelectric characteristics, a light-transmitting structure with the same material, and a same or similar cross-section, for example, as shown in FIGS. 1A, 2A, and 3A. The light of the light-emitting devices of types A to D is emitted through the top surface and the outer side surface of the light-transmitting structure. The light-emitting device of the type A has light-transmitting structure with a square shape from a top view. The light-emitting device of the type B has a light-transmitting structure with a circular shape from a top view, as shown in the above-mentioned light-emitting devices 1001, 1002, 1003. In a top view of the light-emitting device of the type C, the shape of light-transmitting structure has a curved portion and a line portion, as shown in the light-emitting device 2003 in FIG. 4C. The light-emitting device of the type D has a light-transmitting structure with a hexagonal shape from a top view, as shown in the light-emitting device 2001 in FIG. 4A. The second row of the table list shows the top surface area of the light-transmitting structure shown from the top view. The top surface area of the light-transmitting structure of the type A is about 2.56 mm². The top surface area of the light-transmitting structure of the type B is about 1.968 mm². The top surface area of the light-transmitting structure of the type C is about 1.008 mm². The top surface area of the light-transmitting structure of the type D is about 1.664 mm². The luminous flux measured from each of the light-emitting devices of the types A to D is shown in the third row. The luminous fluxes measured from the types A to D are 45.08 lumens, 43.48 lumens, 43.15 lumens, and 39.67 lumens, respectively. Luminous flux can be measured by integrating sphere (for example: Ama Optoelectronics, model LID-100CS). The fourth row in the table shows the luminous flux in per unit area of the light-emitting device (luminous flux/top surface area of the light-transmitting structure). The luminous flux per unit area of the type A light-emitting device is about 17.609. The luminous flux per unit area of the type B light-emitting device is about 21.775. The luminous flux per unit area of the type C light-emitting device is about 39.199. The luminous flux per unit area of the type D light-emitting device is about 23.84. Thus, the light-transmitting structure having a non-rectangular shape results in a greater luminous flux per unit area of light, such as greater than 18, greater than 20, or greater than 25, preferably greater than 30. Therefore, a non-rectangular light-transmitting structure can obtain a similar luminous flux using less light-transmitting material than a rectangular light-transmitting structure.

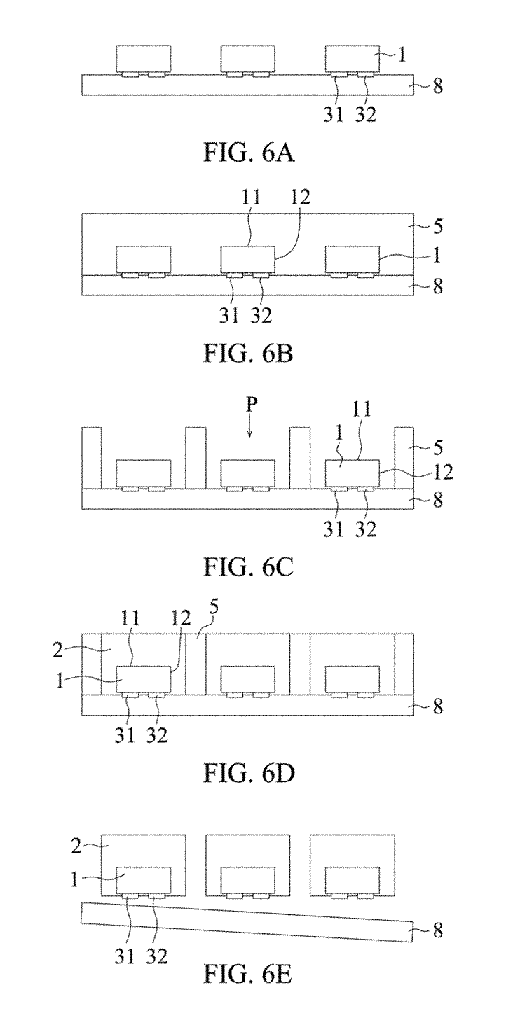

FIGS. 6A to 6E show the diagrams of manufacturing process of a light-emitting device in accordance with an embodiment of the present disclosure. Referring to FIG. 6A, a temporary carrier 8 having adhesiveness is provided first, and a plurality of light-emitting units 1 are placed on the temporary carrier 8. The lower portions of the pair of conductive electrodes 31, 32 are buried in the temporary carrier 8. The area between light-emitting units 1 is defined as a path area, and the accuracy of placing the light-emitting unit 1 on the temporary carrier 8 depends mainly on the accuracy of the pick & place system. Generally the error of the pick & place system does not exceed±15 μm. The temporary carrier 8 may be thermal release tape, UV tape, chemical release tape, heat resistant tape, or blue film. Next, referring to FIG. 6B, a dry film photoresist layer 5 is bonded to the top surface 11 and the side surface 12 of the light-emitting unit 1, and the top surface of the temporary carrier 8 not covered by the light-emitting unit 1. The bonding process is performed by heating and pressing the dry film photoresist layer 5 through an upper mold (not shown) and a lower mold (not shown) to soften the dry film photoresist layer 5 so as to be tightly bonded to the light-emitting unit 1. Moreover, when the upper mold and the lower mold are very close, but the dry film photoresist layer 5 has not contacted the light-emitting unit 1, the air between the dry film photoresist layer 5 and the light-emitting unit 1 can be extracted, and air bubbles between the dry film photoresist layer 5 and the light-emitting unit 1 can be reduced to increase the bonding force between the dry film photoresist layer 5 and the light-emitting unit 1. It should be noted that the dry film photoresist layer 5 may be a multi-layer structure, and the number of layers or the thickness of the layer may be adjusted to adjust the thickness of the dry film photoresist layer 5, thereby changing the optical characteristics of the light-emitting device. In an embodiment, the dry film photoresist layer 5 covering the side surface 12 of the light-emitting unit 1 has a thickness of 300 to 400 μm.

Referring to FIG. 6C, a patterned photo mask (not shown) covers the dry film photoresist layer 5. The patterned photo mask has a plurality of light-transmitting regions and a plurality of opaque regions. The dry film photoresist layer 5 covering the top surface 11 and the side surface 12 of the light-emitting unit 1 is removed by an exposure step (for example, being irradiated by UV light) to form a plurality of openings P, so that the top surface 11 and side surface 12 of the light-emitting unit 1 are exposed. It should be noticed that the masks of different patterns (such as circle, hexagon or square) can be designed according to the shape of the light-transmitting structure 2 of different light-emitting devices (such as FIGS. 1B, 4A, 4B, 4C), so that the shape of the opening P in the top view can be adjusted by the shape of the light-transmitting structure 2. Next, referring to FIG. 6D, the light-transmitting structure 2 can be filled into the opening P by brushing, dispensing, molding, etc., and covers the top surface 11 and the side surface 12 of the light-emitting unit 1. In this step, a planarization process, such as a polish process, may be performed to planarize the top surface of the light-transmitting structure 2. Subsequently, referring to FIG. 6E, the dry film photoresist layer 5 located between the light-transmitting structures 2 is removed, and the temporary carrier 8 is removed. The bottom surfaces of the pair of conductive electrodes 31, 32 and the light-transmitting structure 2 are exposed, and the manufacturing process of the light-emitting device is completed. The method of removing the temporary carrier 8 can be laser peeling, heating separation, dissolution, etc.

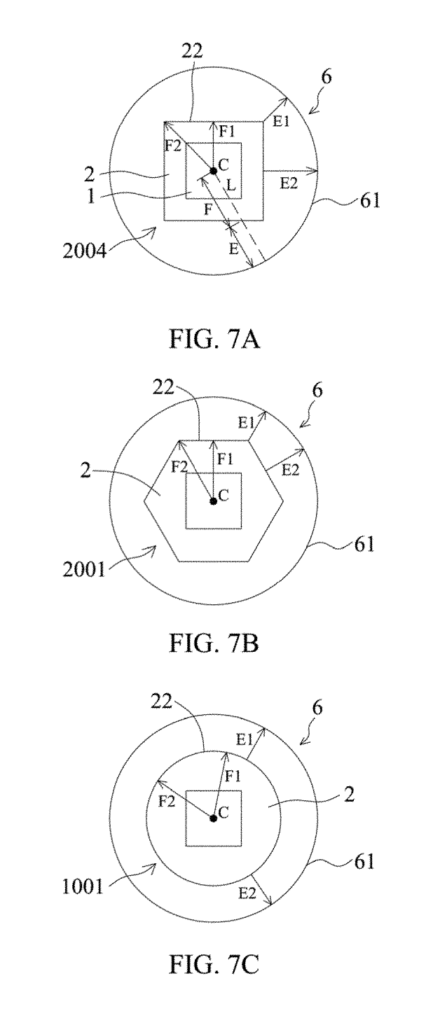

FIGS. 7A to 7C show the top view of the light-emitting devices in accordance with the embodiments of the present disclosure, wherein a circular lens 6 covers the light-emitting device. Taking FIG. 7A as an example, the light-emitting device 2004 is placed in the middle of the lens 6, and the geometric center C of the light-emitting device 2004 overlaps with the geometric center of the lens 6. A straight line L extends from the geometric center C through the light-emitting unit 1, the outer side surface 22 of the light-transmitting structure 2 to the outer side surface 61 of the lens 6. On the straight line L, there is a distance E between the outer side surface of the light-emitting device 2004 (i.e., the outer side surface 22 of the light-transmitting structure 2) and the outer side surface 61 of the lens 6, wherein the shortest distance is E1 and the longest distance is E2. On the straight line L, there is a distance F between geometric center C and the outer side surface of the light-emitting device 2004 (i.e., the outer side surface 22 of the light-transmitting structure 2). The shortest distance of F is F1 and the longest distance is F2. In FIG. 7A, the light-transmitting structure 2 has a rectangular shape similar to that of the light-emitting unit 1 in top upper view. The ratio of the shortest distance F1 and the longest distance F2 of the geometric center C to the outer side surface of the light-emitting device 2004 is not equal to 1, for example, less than 0.75, so that the light intensity of the light emitted by the light-emitting device 2004 is less uniform in all directions after passing through the light-transmitting structure 2. For example, it is stronger along the shortest distance F1 direction and weaker along the longest distance F2 direction. Since the lens 6 has a circular shape, the ratio of the shortest distance E1 and the longest distance E2 of the outer side surface of the light-emitting device 2004 to the outer surface of the lens 6 is not equal to 1, for example, less than 0.6. Therefore the light intensity of the light emitted by the light-emitting device 2004 is less uniform in all directions after passing through the lens 6. For example, it is stronger along the shortest distance E1 direction and weaker along the longest distance E2 direction.

As shown in FIG. 7B, the light-emitting device 2001 is placed in the middle of the lens 6. In the top view, the light-transmitting structure 2 has a regular hexagonal shape different from that of the light-emitting unit 1. The ratio of the shortest distance F1 and the longest distance F2 of the geometric center C to the outer side surface of the light-emitting device 2001 is close to 1, for example, 0.8 to 0.9, so that the light intensity of the light emitted by the light-emitting device 2001 is more uniform in all directions after passing through the light-transmitting structure 2. The ratio of the shortest distance E1 and the longest distance E2 of the light-emitting device 2001 to the outer surface 61 of the lens 6 is also close to 1, for example, 0.7 to 0.9, so that the light intensity of the light emitted by the light-emitting device 2001 is more uniform than the rectangular shape light-transmitting structure (shown in FIG. 7A) in all directions after passing through the lens 6. As shown in FIG. 7C, the light-transmitting structure 2 has a circular shape different from that of the light-emitting unit 1. The ratio of the shortest distance F1 and the longest distance F2 of the geometric center C to the outer side surface of the light-emitting device 1001 is close to 1, for example, 0.9 to 1, so that the light intensity of the light emitted by the light-emitting device 1001 is more uniform in all directions after passing through the light-transmitting structure 2. The ratio of the shortest distance E1 and the longest distance E2 of the light-emitting device 1001 to the outer surface 61 of the lens 6 is also close to 1, for example, 0.9 to 1, so that the light intensity of the light emitted by the light-emitting device 1001 is more uniform than the rectangular or regular hexagonal shape light-transmitting structures (shown in FIGS. 7A, 7B) in all directions after passing through the lens 6.

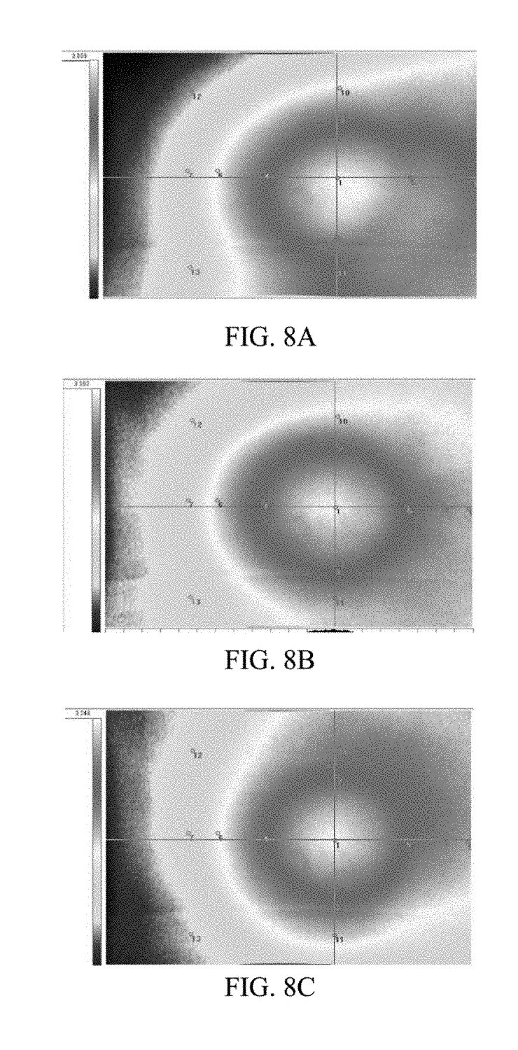

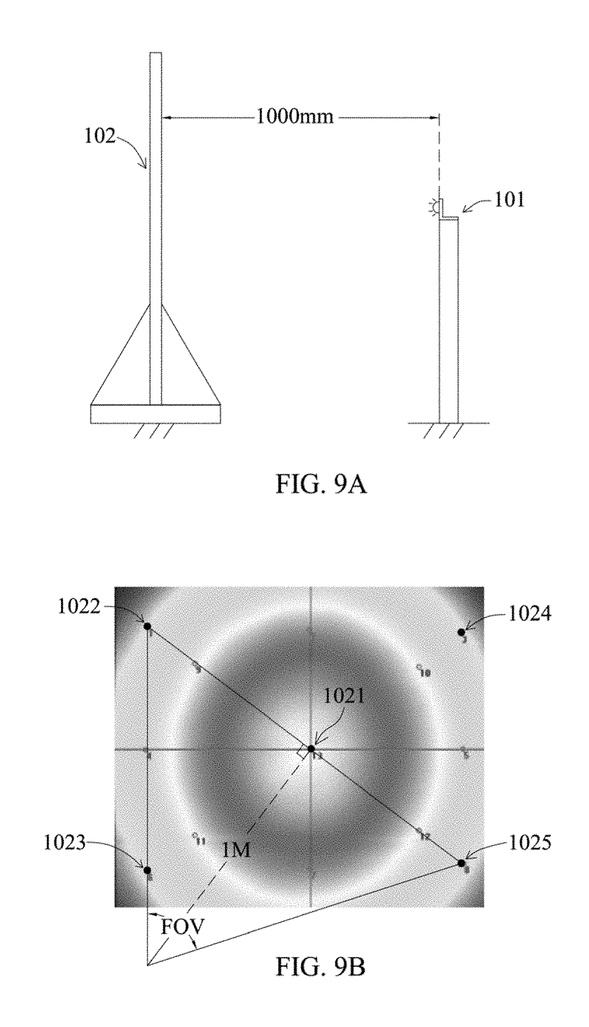

FIGS. 8A to 8C show the light uniformity measurement diagrams of the light-emitting devices in FIGS. 7A to 7C. The method of the light uniformity measurement shown in FIG. 9A includes the following steps: the light-emitting device is fixed on a fixing base 101, the light-emitting device emits light toward the screen 102, and the illuminance of the light-emitting device is measured on the screen 102. The distance between the fixing base and the screen is 1 meter, for example. FIG. 9B shows an illuminance distribution diagram after the screen 102 is illuminated by the light-emitting device. The center point 1021 is the region with the largest illuminance, and the illuminance is getting smaller toward the periphery. The test point on the illuminance profile of FIG. 9B is related to the distance between the center point 1021 and the field of view (FOV) set by the screen 102. For example, when the field of view (FOV) is 78 degrees, the distances between the peripheral test points 1022, 1023, 1024, 1025 and the center point 1021 fall within the range of 79 to 82 cm. The ratio of the minimum illuminance measured from the peripheral test points 1022, 1023, 1024, and 1025 to the illuminance of the center point 1021 is defined as R (Lux). When R (Lux) is closer to 1, it means that the light uniformity of the light-emitting device is better. FIGS. 8A to 8C are illuminance profile diagrams when the field of view (FOV) is 78 degrees. R(Lux) is 0.453 in FIG. 8A, R(Lux) is 0.567 in FIG. 8B, and R(Lux) is 0.523 in FIG. 8C. Therefore, an object illuminated by a non-rectangular shape light-transmitting structure with a circular lens has a more uniform illumination, R (Lux) >0.5.

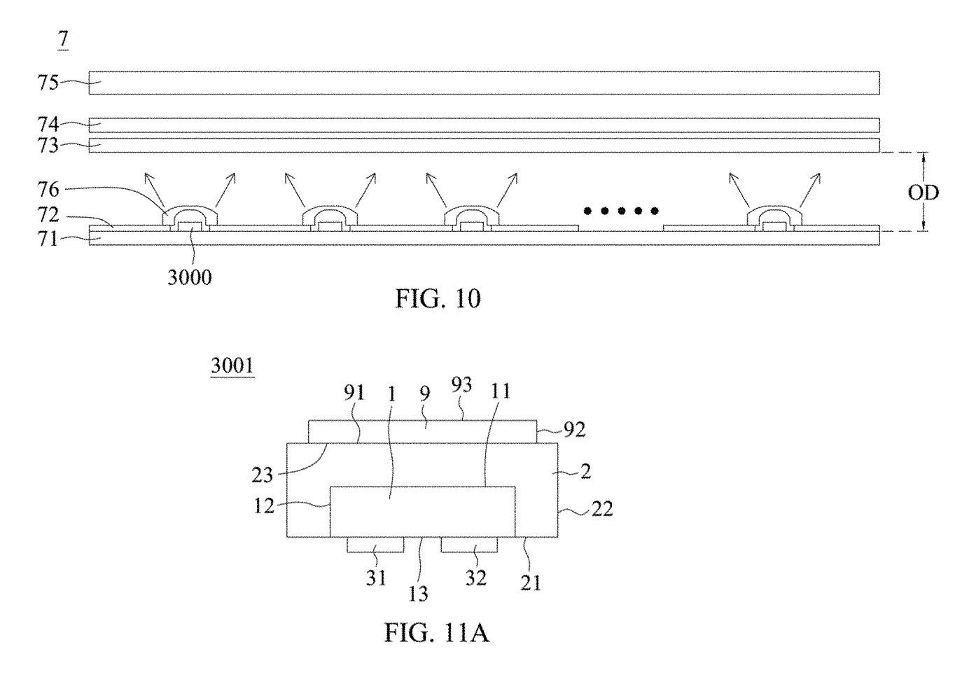

FIG. 10 is a diagram showing a plurality of light-emitting devices (as shown in FIGS. 7A to 7C) placed in the display 7 in accordance with the present disclosure. The display 7 is a display using a direct type backlight module, and includes a liquid crystal display panel 75, an optical layer 74 disposed under a display panel 75, a diffusion layer 73 located below the optical layer 74, a carrier 71 located below the diffusion layer 73, a plurality of light-emitting devices 3000 placed on the carrier 71, each of the plurality of light-emitting devices 3000 is covered by a lens 76, and a reflective layer 72 is formed on the carrier 71 not covered by the light-emitting device 3000. In another embodiment, the carrier 71 is not covered by the reflective layer 72. The distance between the carrier 71 and the diffusion layer 73 is defined as an optical distance (OD). An appropriate optical distance and an arrangement of a diffusion layer can reduce the non-uniform brightness (Mura) of the display panel 75. When the light-emitting device 3000 is the above-mentioned light-emitting device 1001, 1002, 1003, 2001, 2002, or 2003, the uniformity of light emission can be improved with the lens. So that the optical distance (OD) can be reduced, thereby reducing overall thickness of the display 7. When the light-emitting device is the above-mentioned light-emitting device 1001, 1002, 1003, 2001, 2002, or 2003, the OD of the backlight display is not more than 15 mm.

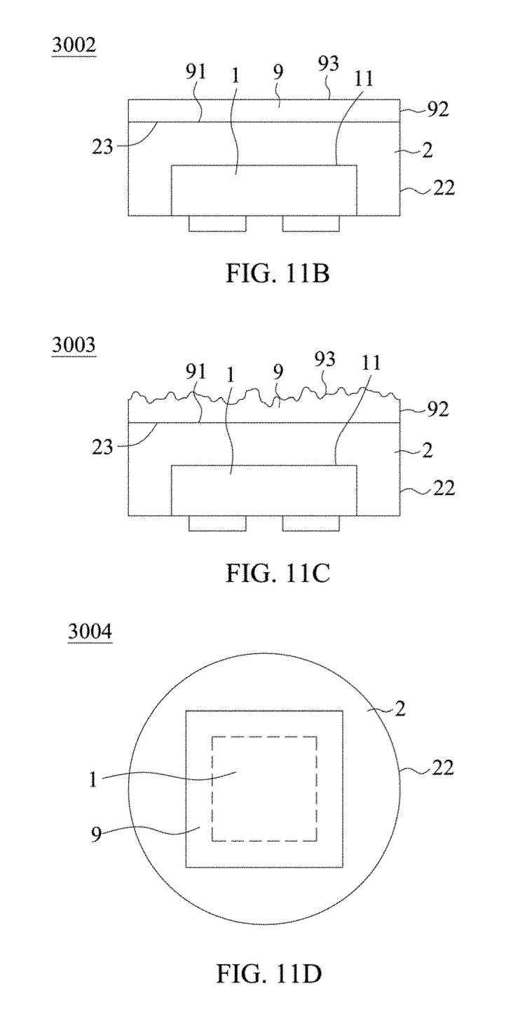

FIGS. 11A to 11C show the cross-sectional views of the light-emitting devices 3001, 3002, and 3003 in other embodiments of the present disclosure, respectively. The light-emitting devices 3001, 3002, and 3003 have a similar structure to the above-mentioned light-emitting devices 1001, 1002, 1003, 2001, 2002, and 2003. The same label or symbol corresponds to the component or device, which has similar or identical component or device. FIG. 11A shows the light-emitting device 3001 including a light-emitting unit 1, a light-transmitting structure 2, a pair of conductive electrodes 31, 32, and an optic structure 9. The light-emitting unit 1 includes a top surface 11, a bottom surface 13 opposite to the top surface 11, and a plurality of side surfaces 12 connecting the top surface 11 and the bottom surface 13. The pair of conductive electrodes 31, 32 is located on the bottom surface 13 of the light-emitting unit 1 and is electrically connected to an external power system. The light-transmitting structure 2 covers the top surface 11 and the plurality of side surfaces 12 of the light-emitting unit 1. The optic structure 9 is formed on the top surface 23 of the light-transmitting structure 2 opposite to the light-emitting unit 1. The bottom surface 91 of the optic structure 9 is in direct contact with the top surface 23 of the light-transmitting structure 2. The outer side surface 92 of the optic structure 9 is not coplanar with the outer side surface 22 of the light-transmitting structure 2, and is closer to the light-emitting unit 1 than the outer side surface 22 of the light-transmitting structure 2 is. Therefore, a portion of the top surface 23 of the light light-transmitting structure 2 is not covered by the optic structure 9. The top surface 93 of the optic structure 9 is a substantially flat surface. The material of the optic structure 9 may comprise silicone, epoxy, Polyimine (PI), benzocyclobutene (BCB), perfluorocyclobutane (PFCB), SUB, Acrylic Resin, polymethyl methacrylate (PMMA), polyethylene terephthalate (PET), polycarbonate (PC), and polyetherimide. Optionally, the optic structure 9 may further comprise diffusion particles or a wavelength-converting material. The material of the diffusing particles comprises titanium dioxide, zirconium oxide, zinc oxide or aluminum oxide, and the light emitted by the light-emitting unit 1 through the light-transmitting structure 2 can be scattered. If the optic structure 9 includes a wavelength-converting material, it may be the same material with the wavelength-converting material of the light-transmitting structure 2. If the materials are the same, the wavelength-converting materials of the optic structure 9 and the light-transmitting structure 2 may have different concentrations, for example, the concentration of the wavelength-converting material in the optic structure 9 is higher than the concentration of the wavelength-converting material in the light-transmitting structure 2. The wavelength-converting material in the optic structure 9 may be different with the wavelength-converting material of the light-transmitting structure 2, for example, the optic structure 9 contains a shorter wavelength phosphor (for example, yellow/yellow green phosphor), and the light light-transmitting structure 2 contains a longer wavelength phosphor (for example, red phosphor). Therefore, a part of the light emitted from the top surface 23 of the light-transmitting structure 2 passes through the optic structure 9 to change the characteristics of the light, such as the color temperature or the illumination angle. The other part of light does not pass through the optic structure 9 and be emitted directly.

The outer side surface 92 of the optic structure 9 may also be coplanar with the outer side surface 22 of the light-transmitting structure 2, as shown in FIG. 8B. FIG. 11B shows the light-emitting device 3002, and all the light emitted from the top surface 23 of the light-transmitting structure 2 is emitted upward through the optic structure 9. The top surface of the optic structure 9 may also have a rough surface as shown in FIG. 11C. FIG. 11C shows a light-emitting device 3003 and the top surface 93 of the optic structure 9 has a rough surface. In an embodiment, the shape of the optic structure 9 is similar to the shape of the light-transmitting structure 2 from the top view. In another embodiment, as shown in FIG. 11D, the shape of the optic structure 9 is different from the shape of the light-transmitting structure 2. For example, the shape of the light-transmitting structure 2 is circular, and the shape of the optical structure 9 is rectangular. However, the above-mentioned shape does not limit the scope of the present disclosure.

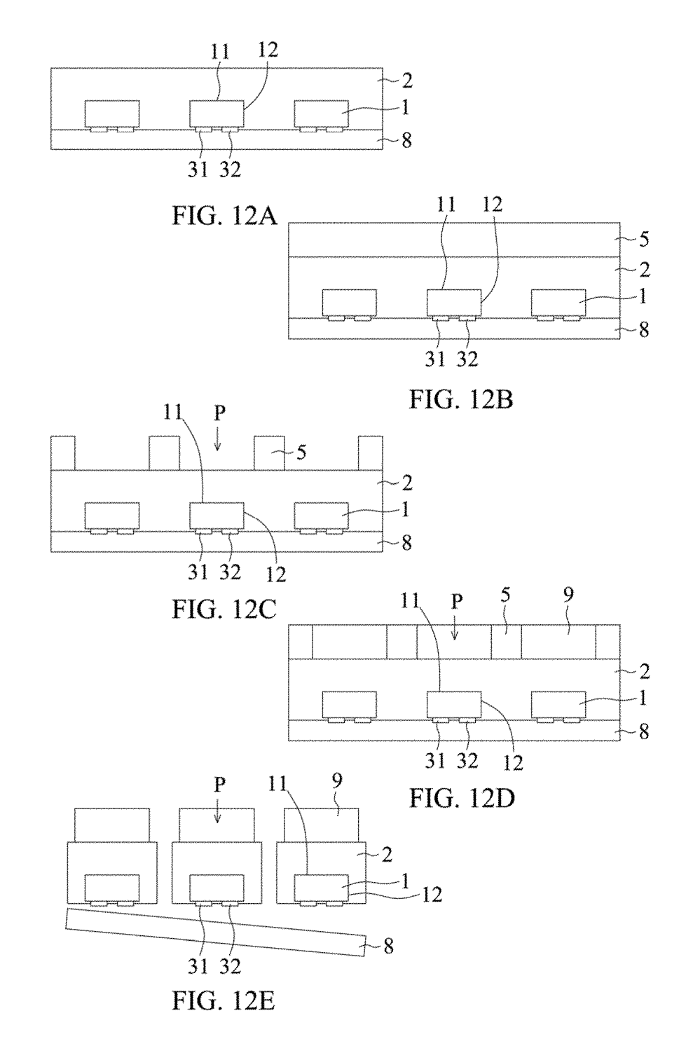

FIGS. 12A to 12E show the diagrams of manufacturing process of a light-emitting device in accordance with an embodiment of the present disclosure. Referring to FIG. 12A, a temporary carrier 8 having adhesiveness is provided first and a plurality of light-emitting units 1 are placed on the temporary carrier 8. The lower portions of the pair of conductive electrodes 31, 32 are buried into the temporary carrier 8. The area between adjacent light-emitting units 1 is defined as a path area. The light-transmitting structure 2 is formed by steel plate printing, coating, brushing, spin coating, ink jet printing, dispensing, mold filling, etc. to cover the top surface 11 and the side surface 12 of the light-emitting unit 1 and the path area. In this step, a planarization process, such as a polish process, may be performed to planarize the top surface of the light-transmitting structure 2. Next, referring to FIG. 12B, a dry film photoresist layer 5 is bonded on the light-transmitting structure 2. The bonding process is performed by heating and pressing the dry film photoresist layer 5 through an upper mold (not shown) and a lower mold (not shown) to soften the dry film photoresist layer 5 so as to be tightly bonded to the light-transmitting structure 2. Moreover, when the upper mold and the lower mold are very close, and the dry film photoresist layer 5 has not contacted the light-transmitting structure 2, the air between the dry film photoresist layer 5 and the light-transmitting structure 2 can be extracted, and air bubbles between the dry film photoresist layer 5 and the light-transmitting structure 2 can be reduced to increase the bonding force between the dry film photoresist layer 5 and the light-transmitting structure 2. It should be noted that the dry film photoresist layer 5 may be a multi-layer structure, and the number of layers or the thickness of the layer may be adjusted to adjust the thickness of the dry film photoresist layer 5, thereby changing the optical characteristics of the light-emitting device. Referring to FIG. 12C, a patterned photo mask (not shown) covers the dry film photoresist layer 5. The patterned photo mask has a plurality of light-transmitting regions and a plurality of opaque regions. The dry film photoresist layer 5 covering the light-emitting unit 1 is removed by an exposure step (for example, being irradiated by UV light) to form a plurality of openings P, so that the light-transmitting structure 2 above the light-emitting unit 1 are exposed. It should be noticed that the patterns of the masks can be designed according to the shape of the optic structure 9 of different light-emitting devices (such as those disclosed in FIGS. 11A to 11D), so that the shape of the opening P from the top view can be adjusted by the shape of the optic structure 9. Next, referring to FIG. 12D, the optic structure 9 can be filled into the opening P by brushing, dispensing, molding, etc., and covers the light-transmitting structure 2. In this step, a planarization process, such as a polish process, may be performed to planarize the top surface of the optic structure 9. Subsequently, referring to FIG. 12E, the dry film photoresist layer 5 located between the optic structures 9 is removed, the light-transmitting structure 2 is cutting, and the temporary carrier 8 is removed. The bottom surfaces of the pair of conductive electrodes 31, 32 and the light-transmitting structure 2 are exposed and the manufacturing process of the light-emitting device is completed. In another embodiment (not shown), in the step disclosed in FIG. 12E, a wide knife having a width wider than the width of the dry film photoresist layer 5 may also be used to cut the dry film photoresist layer 5 before it is removed while removing the dry film photoresist layer 5 and separating the light-emitting devices, and then removing the temporary carrier 8.

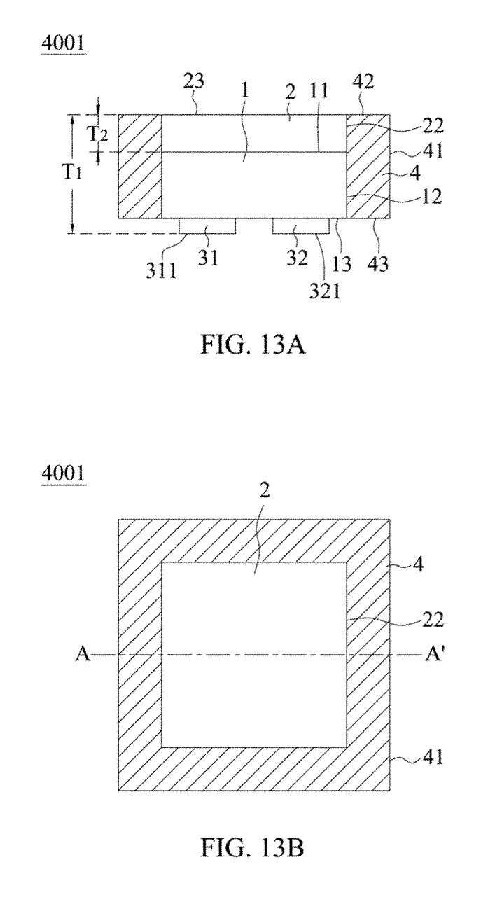

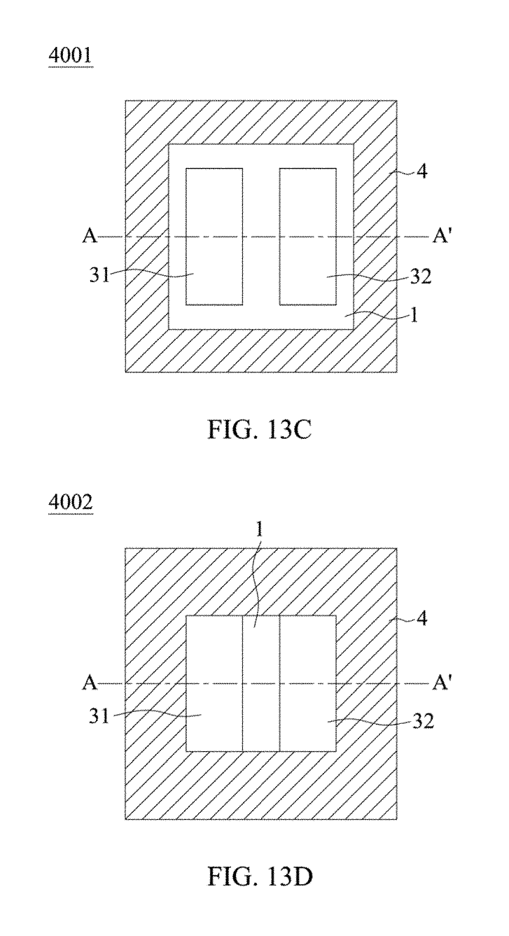

FIG. 13A shows a cross-sectional view of a light-emitting device 4001 in accordance with an embodiment of the present disclosure. FIG. 13B shows a top view of the light-emitting device 4001 in an embodiment of the present disclosure. FIG. 13C shows a bottom view of the light-emitting device 4001 in an embodiment of the present disclosure. FIG. 13A is a cross-sectional view of the AA′ line in FIG. 13B and FIG. 13C. The light-emitting device 4001 includes a light-emitting unit 1, a light-transmitting structure 2, a pair of conductive electrodes 31, 32, and a light-blocking structure 4. Referring to FIG. 13A, the light-emitting unit 1 includes a top surface 11, a bottom surface 13 opposite to the top surface 11, and a plurality of side surfaces 12 connecting the top surface 11 and the bottom surface 13. The light-transmitting structure 2 covers the top surface 11 of the light-emitting unit 1 and has an outer side surface 22. The outer side surface 22 of the light-transmitting structure 2 does not extend outward beyond the side surface 12 of the light-emitting unit 1. Referring to FIG. 13A, the outer side surface 22 of the light-transmitting structure 2 is substantially coplanar with the side surface 12 of the light-emitting unit 1. A light-blocking structure 4 covers the side surface 12 of the light-emitting unit 1 and the outer side surface 22 of the light-transmitting structure 2. The light-blocking structure 4 has a top surface 42 that is substantially coplanar with the top surface 23 of the light-transmitting structure 2. Referring to FIG. 13B, the light-blocking structure 4 surrounds the light-transmitting structure 2 from the top view. Therefore, the light emitted by the light-emitting unit 1 does not leave from the outermost surface 41 of the light-emitting device 4001, but leaves the light-emitting device 4001 only from the top surface of the light-emitting device 4001, which is also the top surface 23 of the light-transmitting structure 2. The material of the light-blocking structure 4 may be a reflective material or a light-shielding material. The reflective material may comprise a mixture of a based material and a high reflectivity material. The based material can be a silicone-based or epoxy-based. The high reflectivity material may comprise titanium dioxide, silicon dioxide, or aluminum oxide. The light-shielding material does not reflect light and can shield a part of light from the light-emitting unit 1. The light-shielding material is dark (for example: black, gray, or other dark colors) and opaque material. The opaque material may comprise Bismaleimide Triazine Resin (BT), and the surface may be coated with a material that can shield visible light, such as black ink or light-shielding layer. The material of the light-shielding layer may comprise metal, resin, or graphite. The material of metal can be Chromium. The resin may be composed of polyimide (PI) or acrylate, and a light-absorbing material such as carbon or titanium oxide may be dispersed in the resin. The color of the light-shielding layer is preferably dark, such as black, brown, or gray. When the inner surface of the light-blocking structure 4 contacted the side surface 12 of light-emitting unit is a reflecting surface, it helps to increase the luminous flux of the light-emitting device.

In another embodiment, the top surface 23 of the light-transmitting structure 2 has a rough surface (not shown) to increase the amount of light emitted. The pair of conductive electrodes 31, 32 is located on the bottom surface 13 of the light-emitting unit 1 and can be electrically connected to the power supply system. The bottom surfaces 311, 321 of the pair of conductive electrodes 31, 32 are not flush with the bottom surface 13 of the light-emitting unit 1 and the bottom surface 21 of the light-transmitting structure 2. The bottom surface 13 of the light-emitting unit 1 is substantially flush with the bottom surface 21 of the light-transmitting structure 2. Referring to FIG. 13C, the light-blocking structure 4 does not cover the bottom surface 13 of the light-emitting unit 1, and the pair of conductive electrodes 31, 32 are located on a portion of the bottom surface 13 of the light-emitting unit 1. Therefore, a part of the light of the light-emitting unit 1 is emitted from the bottom surface 13 without passing through the light-transmitting structure 2. The shapes of the pair of conductive electrodes 31, 32 disclosed herein are merely exemplified, and the shape, size, and arrangement of the conductive electrodes are not limited thereto. In another embodiment, the light-blocking structure 4 covers a portion of the bottom surface 13 of the light-emitting unit 1. As shown in FIG. 13D, the light-blocking structure 4 of the light-emitting device 4002 covers the bottom surface 13 of the light-emitting unit 1 between the pair of conductive electrodes 31, 32 and the side surface 12. From the bottom view, the light-blocking structure 4 covers the outer side surfaces of the pair of conductive electrodes 31, 32, but does not cover the whole or partially the bottom surface 13 between the pair of conductive electrodes 31 and 32. If the only difference is the areas covered by the light-blocking structure 4, the light-emitting device 4002 can emit less light from the bottom surface 13 of the light-emitting unit 1 than the light-emitting device 4001 can. In particular, when the light-emitting device 4002 is fixed to a circuit carrier (not shown), the light emitted from the bottom surface 13 of the light-emitting unit 1 of the light-emitting device 4002 is almost shielded by the circuit carrier.

The light-emitting direction of the light-emitting device 4001 is in a single direction. As the above-mentioned description, the light-transmitting structure 2 is surrounded by the light-blocking structure 4, and the light emitted by the light-emitting unit 1 exits the light-emitting device 4001 only via the top surface 23 of the light-transmitting structure 2. Therefore, the light-emitting device 4001 has an illumination angle less than 120 degrees, preferably no more than 115 degrees. The illumination angle described herein is defined as the range of angles that are included when the brightness is 50% of the maximum brightness. A detailed description of the illumination angle can refer to the content of the Taiwan patent application numbered 104103105, which is also cited as the content of the present disclosure. The light-emitting device 4001 has a total height T1. The light-transmitting structure 2 has a height T2. The height T2 of the light-transmitting structure 2 is 0.4-0.7 of the total height T1 of the light-emitting device 4001. In an embodiment, T1 is not greater than 300 μm, 260 μm, or 250 μm. T2 is not greater than 120 μm. The height of the light-transmitting structure 2 is a key parameter relating to the color temperature and color uniformity of the light emitted by the light-emitting device 4001.

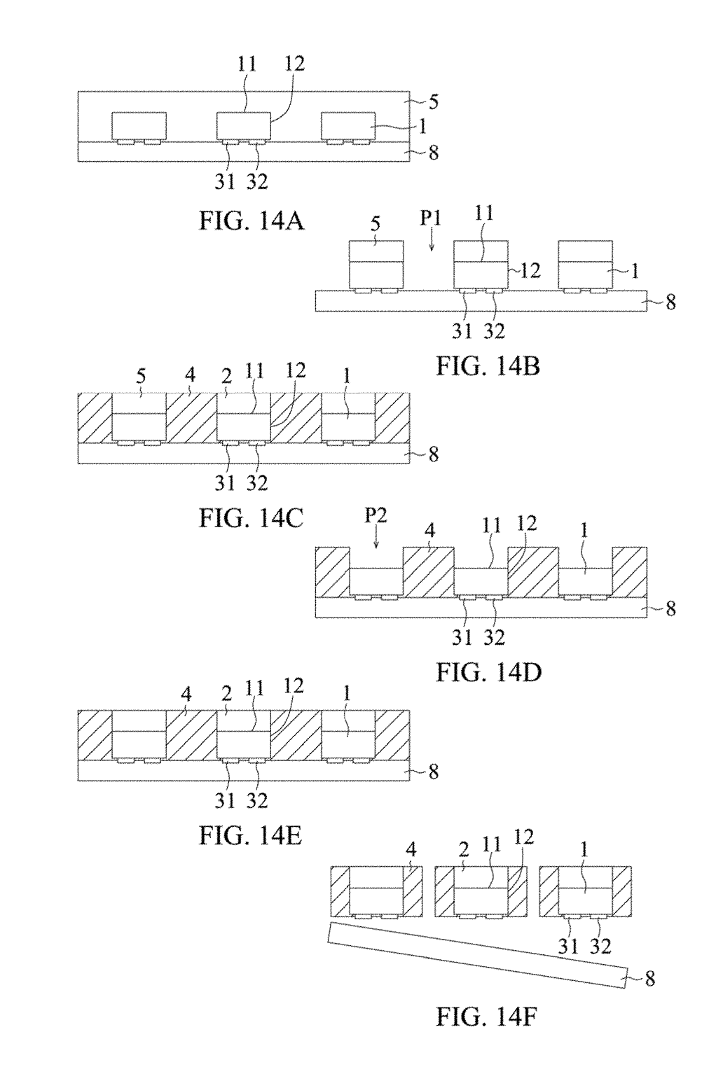

FIGS. 14A to 14E show the diagrams of manufacturing process of a light-emitting device in accordance with an embodiment of the present disclosure. Referring to FIG. 14A, a temporary carrier 8 having adhesiveness is provided first, and a plurality of light-emitting units 1 is placed on the temporary carrier 8. The lower portions of the pair of conductive electrodes 31, 32 are buried in the temporary carrier 8. The area between light-emitting units 1 is defined as a path area. Next, a dry film photoresist layer 5 is bonded to the top surface 11 and the side surface 12 of the light-emitting unit 1, and the top surface of the temporary carrier 8 not covered by the light-emitting unit 1. The bonding process is performed by heating and pressing the dry film photoresist layer 5 through an upper mold (not shown) and a lower mold (not shown) to soften the dry film photoresist layer 5 so as to be tightly bonded to the light-emitting unit 1. Moreover, when the upper mold and the lower mold are very close, but the dry film photoresist layer 5 has not contacted the light-emitting unit 1, the air between the dry film photoresist layer 5 and the light-emitting unit 1 can be extracted, and air bubbles between the dry film photoresist layer 5 and the light-emitting unit 1 can be reduced to increase the bonding force between the dry film photoresist layer 5 and the light-emitting unit 1. It should be noted that the dry film photoresist layer 5 may be a multi-layer structure, and the number of layers or the thickness of the layer of may be adjusted to adjust the thickness of the dry film photoresist layer 5, thereby changing the optical characteristics of the light-emitting device. Next, Referring to FIG. 14B, a patterned photo mask (not shown) covers the dry film photoresist layer 5. The patterned photo mask has a plurality of light-transmitting regions and a plurality of opaque regions. The dry film photoresist layer 5 covering the path area is removed by an exposure step (for example, being irradiated by UV light) to form a plurality of openings P1, so that the side surfaces 12 of the light-emitting unit 1 are exposed. At this time, the top surface 11 of the light-emitting unit 1 is still covered by the dry film photoresist layer 5. Next, referring to FIG. 14C, the light-blocking structure 4 can be filled into the opening P1 by brushing, dispensing, molding, etc. Referring to FIG. 14D, the dry film photoresist layer 5 located above the light-emitting unit 1 is removed to form a plurality of openings P2.

Next, referring to FIG. 14E, the light-transmitting structure 2 can be filled into the opening P2 by brushing, dispensing, molding, etc. to cover the top surface 11 of the light-emitting unit 1. In this step, a planarization process, such as a polish process, may be performed to planarize the top surface of the light-transmitting structure 2 and the top surface of the light-blocking structure 4(coplanar or near coplanar). Finally, referring to FIG. 14F, the light-blocking structure 4 is cutting, and the temporary carrier 8 is removed. The bottom surfaces of the pair of conductive electrodes 31, 32 are exposed and the manufacturing process of the light-emitting device is completed.

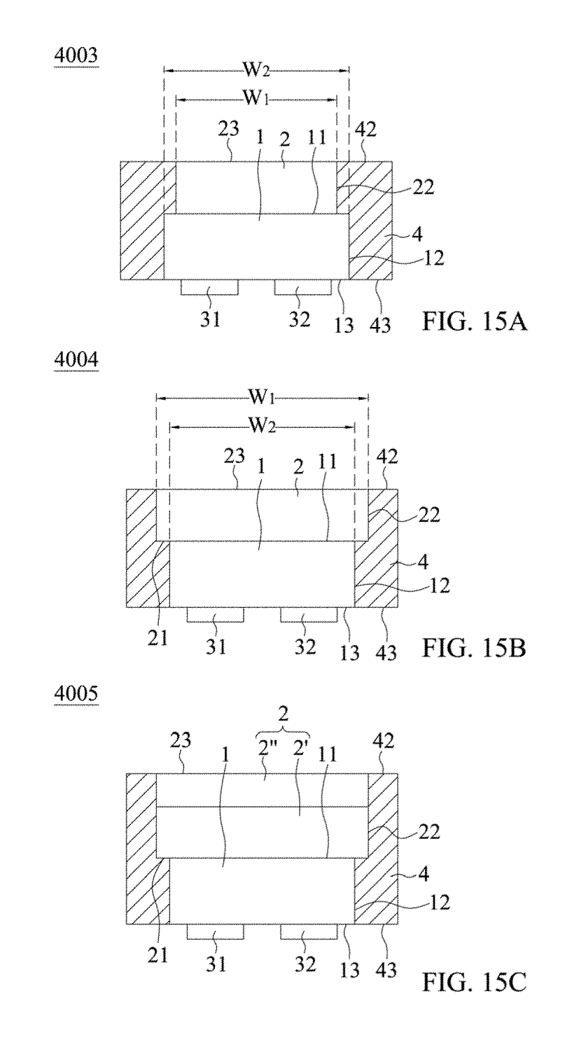

In another embodiment, the outer side surface 22 of the light-transmitting structure 2 is retracted to the side surface 12 of the light-emitting unit 1 as shown in FIG. 15A. The light-emitting device 4003 has a structure similar to the above-mentioned light-emitting devices 4001 and 4002. The same label or symbol corresponds to the component or device, which has similar or identical component or device. The outer side surface 22 of the light-transmitting structure 2 is not coplanar with the side surface 12 of the light-emitting unit 1. Therefore, part of the top surface 11 of the light-emitting unit 1 is covered by the light-blocking structure 4. In other words, the light-transmitting structure 2 has a maximum width W1 and the light-emitting unit 1 has a maximum width W2. W1 is smaller than W2. In another embodiment, the outer side surface 22 of the light-transmitting structure 2 is beyond the side surface 12 of the light-emitting unit 1, as shown in FIG. 15B. The light-emitting device 4004 has a structure similar to the above-mentioned light-emitting devices 4001 and 4002. The same label or symbol corresponds to the component or device, which has similar or identical component or device. The outer side surface 22 of the light-transmitting structure 2 is not coplanar with the side surface 12 of the light-emitting unit 1. Therefore, part of the bottom surface 21 of the light-transmitting structure 2 is covered by the light-blocking structure 4. In other words, the light-transmitting structure 2 has a maximum width W1 and the light-emitting unit 1 has a maximum width W2. W1 is larger than W2. In an embodiment, the difference between W1 and W2 is not more than 10 μm.

In an embodiment, the light-transmitting structure 2 may be a multilayer structure. Referring to FIG. 15C, the above-mentioned light-transmitting structure 2 of the light-emitting device can be a multilayer structure as shown in FIG. 15C. The outer side surface 22 of the light-transmitting structure 2 of the light-emitting device 4005 is not coplanar with the side surface 12 of the light-emitting unit 1. A portion of the bottom surface 21 of the light-transmitting structure 2 does not overlap the top surface 11 of the light-emitting unit 1, and is covered by the light blocking structure 4. The light-transmitting structure 2 is a multilayer structure having at least one layer. The multilayer structure may comprise a first light-transmitting layer 2′ and a second light-transmitting layer 2″ covering the first light-transmitting layer 2′. The top surface of the second light-transmitting layer 2″ is the top surface 23 of the light-transmitting structure 2 and is substantially coplanar with the top surface 42 of the light-blocking structure 4. The whole first light-transmitting layer 2′ is covered by the light-blocking structure 4, the light-emitting unit 1, and the second light-transmitting layer 2″ so that the first light-transmitting layer 2′ is isolated with the environmental medium (such as air, moisture, the gas released from the structure and material, and the gas used in the process). The first light-transmitting layer 2′ may comprise Silicone, Epoxy, Polyimine (PI), Benzocyclobutene (BCB), Perfluorocyclobutane (PFCB), SU8, Acrylic Resin, Polymethyl Methacrylate (PMMA), Polyethylene terephthalate (PET), Polycarbonate (PC), Polyetherimide. The first light-transmitting layer 2′ may comprise the above-mentioned wavelength-converting material. The second light-transmitting layer 2″ may comprise the same material with the first light-transmitting layer 2′, so that the bonding property between the first light-transmitting layer 2′ and the second light-transmitting layer 2″ is better. In an embodiment, the second light-transmitting layer 2″ may comprise the same or different wavelength-converting material with the first light-transmitting layer 2′, or the above-mentioned diffusion particles used to scatter the light emitted from the first light-transmitting layer 2′. In an embodiment, the second light-transmitting layer 2″ is a light-transmitting material that does not comprise a wavelength-converting material. In an embodiment, the second light-transmitting layer 2″ may be one or more layers of oxide, nitride, polymer, or a combination thereof, such as silicon oxide, aluminum oxide, silicon nitride or Parylene and can block the outside moisture and oxygen.

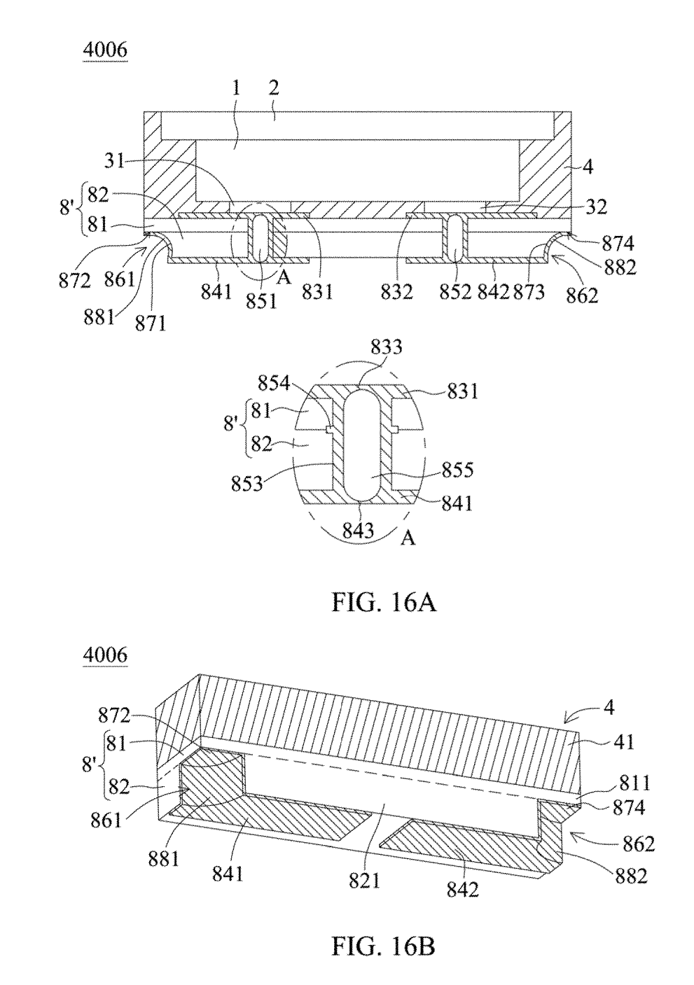

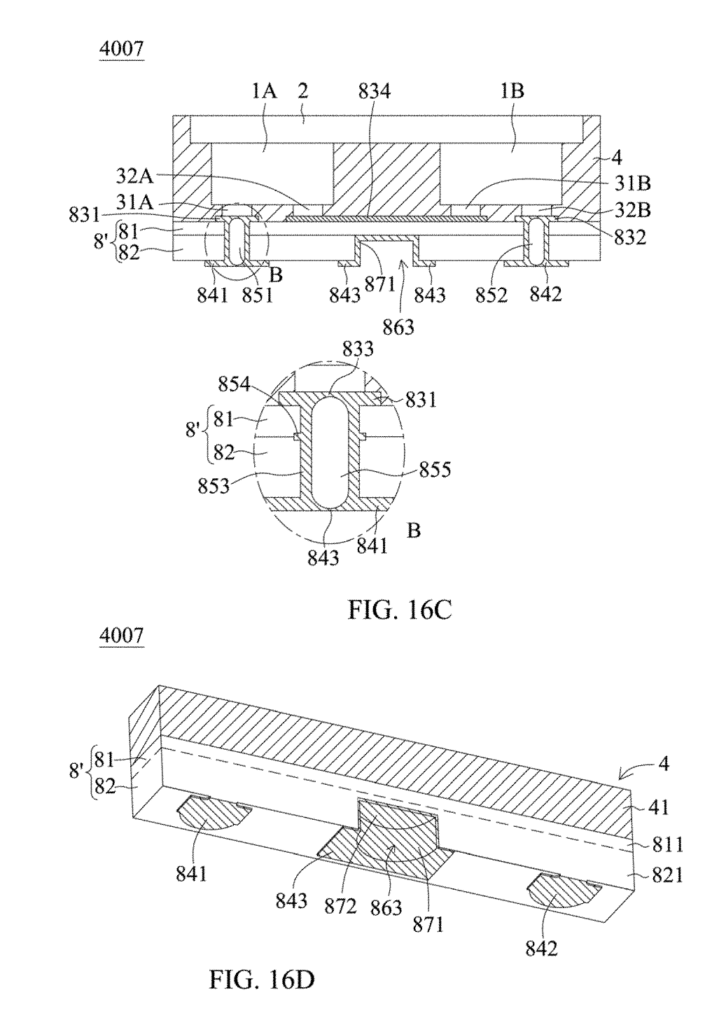

In an embodiment, in the process disclosed in FIGS. 14A˜14F, the temporary carrier 8 is replaced by a support structure 8′. In the step of cutting and separating the light-emitting devices, the support structure 8′ is cut and separated to form the light-emitting device. As shown in FIG. 16A, the light-emitting device 4006 has a support structure 8′, the light-emitting unit 1 located above the support structure 8′, the light-transmitting structure 2 located above the light-emitting unit 1, and the light-blocking structure 4 surrounding the light-emitting unit 1 and the light-transmitting structure 2. The related description of the light-emitting unit 1, the light-transmitting structure 2, and the light-blocking structure 4 can be referred to the above-mentioned description of FIG. 15B. FIG. 16B is a schematic view of the light-emitting device 4006. The support structure 8′ includes a first support plate 81 and a second support plate 82 which is located below the first support plate 81. The thickness of the first support plate 81 is smaller than the thickness of the second support plate 82. The top surface of the first support plate 81 has a first conductive layer 831 and a second conductive layer 832. The bottom surface of the second support plate 82 has a third conductive layer 841 and a fourth conductive layer 842. The bottom surface of the first support plate 81 is attached to the top surface of the second support plate 82. A first via hole 851 penetrates the first support plate 81 and the second support plate 82, and has a conductive material on the inner wall of the first via hole 851 for forming electrical connection with the first conductive layer 831 and the third conductive layer 841. A second via hole 852 penetrates the first support plate 81 and the second support plate 82, and has a conductive material on the inner wall of the second via hole 852 for forming electrical connection with the second conductive layer 832 and the fourth conductive layer 842. Referring to the enlarged view A showing the first via hole 851 in FIG. 16A, a conductive layer 853 is located on the inner wall of the first via hole 851 and an insulating material 855 is located inside the first via hole 851 and surrounded by the conductive layer 853. The conductive layer 853 has a protrusion 854 located at the junction of the first support plate 81 and the second support plate 82. An insulating material 855, such as resin, may protrude beyond the top surface of the first support plate 81 and the bottom surface of the second support plate 82 to form a curved surface. Therefore the portion 833 of the first conductive layer 831 on the insulating material 855 is thinner than other portions, and the portion 843 of the third conductive layer 841 on the insulating material 855 is thinner than other portions. In another embodiment, the insulating material 855 does not protrude beyond the top surface of the first support plate 81 and the bottom surface of the second support plate 82. Therefore the portion 833 of the first conductive layer 831 on the insulating material 855 has substantially equal thickness with that of other portions, and the portion 843 of the third conductive layer 841 under the insulating material 855 has substantially equal thickness with that of the other portions. The detailed description of the second via hole is same with the first via hole.

Referring to FIGS. 16A and 16B, at two corners of the support structure 8′, the first through hole 861 only passes through the second support plate 82 to form a curved side surface 871 and exposes a portion of the bottom surface 872 of the first support plate 81; the second through hole 862 only passes through the second support plate 82 to form a curved side surface 873 and exposes a portion of the bottom surface 874 of the first support plate 81. An extended conductive layer 881 is located on the bottom surface 872 of the first support plate 81 not covered by the second support plate 82 and the curved side surface 871 of the second support plate 82.The extended conductive layer 881is electrically connected to the third conductive layer 841. An extended conductive layer 882 is located on the bottom surface 874 of the first support plate 81 not covered by the second support plate 82 and the curved side surface 873 of the second support plate 82. The extended conductive layer 882 is electrically connected to the fourth conductive layer 842. It should be noted that the first through hole 861 and the second through hole 862 are located on the same side of the long side of the support structure 8′ without touching the opposite side of the long side. Therefore, the second support plate 82 is substantially flat with respect to the outer side surface of the through hole. The materials of the first support plate 81 and the second support plate 82 may be the same or different organic materials, such as phenolic resin, glass fiber, epoxy resin, polyimide or bismaleimide-triaza Benzene resin (BT), or the same or different inorganic materials, such as aluminum or ceramic materials, or a combination of the above materials.

The conductive electrode 31 on the bottom surface of the light-emitting unit 1 is located on the first conductive layer 831 and is electrically connected thereto. The conductive electrode 32 on the bottom surface of the light-emitting unit 1 is located on the second conductive layer 832 and is electrically connected thereto. The light-blocking structure 4 surrounds the outer side surfaces of the light-emitting unit 1, the light-transmitting structure 2, the pair of conductive electrodes 31, 32, the first conductive layer 831, and the second conductive layer 832. The light-blocking structure 4 covers the top surface of the first support plate 81 not covered by the first conductive layer 831 and the second conductive layer 832, and fills the region between the pair of conductive electrodes 31, 32, and between the first conductive layer 831 and the second conductive layer 832. The outermost surface 41 of the light-blocking structure 4 is substantially coplanar with the outermost surface 811 of the first support plate 81 and the outermost surface 821 of the second support plate 82.

In another embodiment, the light-emitting device can comprise a plurality of light-emitting units, as shown in FIG. 16C. Referring to FIG. 16C, the light-emitting device 4007 includes a support structure 8′, the light-emitting units 1A, 1B located above the support structure 8′, a light-transmitting structure 2 located above the light-emitting units 1A, 1B, and a light-blocking structure 4 surrounding the light-emitting units 1A, 1B and the light-transmitting structure 2. The related description of the light-emitting units 1A, 1B, the light-transmitting structure 2, and the light-blocking structure 4 can be referred to the above-mentioned descriptions of the FIGS. 16A-16B. FIG. 16D is a schematic view of the light-emitting device 4007. The support structure 8′ includes a first support plate 81 and a second support plate 82 located below the first support plate 81. A first conductive layer 831, a second conductive layer 832 and a fifth conductive layer 834 are located on the top surface of the first support plate 81 for electrically connecting the light-emitting units 1A, 1B. A third conductive layer 841, a fourth conductive layer 842 and a sixth conductive layer 843 are located on the bottom surface of the second support plate 82. The bottom surface of the first support plate 81 is attached to the top surface of the second support plate 82. A first via hole 851 penetrates the first support plate 81 and the second support plate 82, and a conductive material is located on the inner wall of the first via hole 851 for forming electrical connection with the first conductive layer 831 and the third conductive layer 841. A second via hole 852 penetrates the first support plate 81 and the second support plate 82, and a conductive material is located on the inner wall of the second via hole 852 for forming electrical connection with the second conductive layer 832 and the fourth conductive layer 842. A detailed description of the first via hole and the second via hole can be referred to the enlarged view B of FIG. 16C and the above-mentioned description of FIG. 16A.

Referring to FIG. 16C and FIG. 16D, there is a through hole 863 in the middle of the support structure 8′. The through hole 863 passes through only the second support plate 82 to form a curved side surface 871 (referring to FIG. 16D), and a portion of the bottom surface 872 of the first support plate 81 is exposed. A conductive layer is located on the bottom surface 872 of the first support plate 81 not covered by the second support plate 82 and on the curved side surface 871 of the second support plate 82, the conductive layer extends along the bottom surface of the second support plate 82 and are electrically connected to the sixth conductive layer 843. It should be noted that the through hole 863 is located on the long side of the support structure 8′ without touching the opposite side of the long side. Therefore, the second support plate 82 is substantially flat with respect to the outer side surface of the through hole.

The conductive electrode 31A on the bottom surface of the light-emitting unit 1A is located on the first conductive layer 831 and is electrically connected thereto. The conductive electrode 32A is located on the fifth conductive layer 834 and is electrically connected thereto. The conductive electrode 31B on the bottom surface of the light-emitting unit 1B is located on the fifth conductive layer 834 and is electrically connected thereto. The conductive electrode 32B is located on the second conductive layer 832 and is electrically connected thereto. The light-blocking structure 4 surrounds the outer side surfaces of the light-emitting units 1A, 1B, the light-transmitting structure 2, the pairs of conductive electrodes 31A, 32A, 31B, 32B, the first conductive layer 831, the second conductive layer 832 and the fifth conductive layer 834. The light-blocking structure 4 covers the top surface of the first support plate 81 not covered by the first conductive layer 831, the second conductive layer 832 and the fifth conductive layer 834, and fills the region between the pairs of conductive electrodes 31A, 32A, 31B, 32B, between the first conductive layer 831 and the fifth conductive layer 834, and between the second conductive layer 832 and the fifth conductive layer 834. The outermost surface 41 of the light-blocking structure 4 is substantially coplanar with the outermost surface 811 of the first support plate 81 and the outermost surface 821 of the second support plate 82.

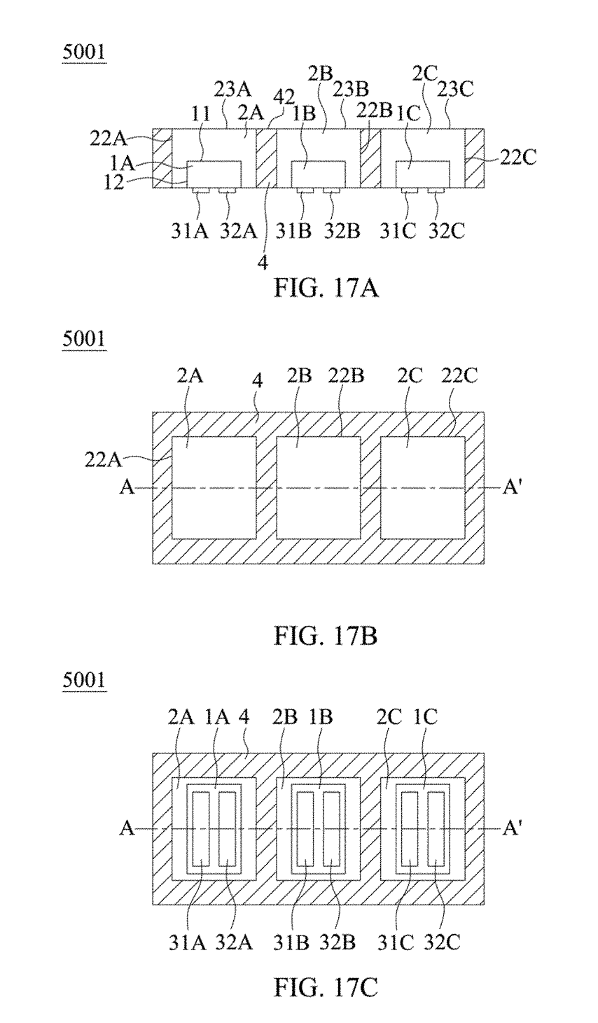

In one embodiment, in the manufacturing process disclosed in FIGS. 14A to 14F, a light-emitting device having a plurality of light-emitting units can be formed by arranging the light-blocking structure and choosing the position at where the light-blocking structure is cut as FIGS. 17A to 17C shows. FIG. 17A shows a cross-sectional view of a light-emitting device 5001 in accordance with an embodiment of the present disclosure. FIG. 17B shows a top view of the light-emitting device 5001 disclosed in an embodiment of the present disclosure. FIG. 17C shows a bottom view of the light-emitting device 5001 in an embodiment of the present disclosure. FIG. 17A shows a cross-sectional view of the line AA′ in FIG. 17B. The light-emitting device 5001 includes a plurality of light-emitting units 1A, 1B, 1C, a plurality of light-transmitting structures 2A, 2B, 2C separated from each other, a plurality of pairs of conductive electrodes 31A, 32A, 31B, 32B, 31C, 32C, and a light-blocking structure 4. The light-transmitting structure 2A covers the top surface 11 and the side surface 12 of the light-emitting unit 1A. Similarly, the light-transmitting structure 2B covers the top surface and the outer side surface of the light-emitting unit 1B. The light-transmitting structure 2C covers the top surface and the outer side surface of the light-emitting unit 1C. The light-blocking structure 4 surrounds the plurality of light-emitting units 1A, 1B, 1C and is located between the light-transmitting structures 2A, 2B, 2C and in contact with the outer side surfaces 22A, 22B, 22C of the light-transmitting structures 2A, 2B, 2C. The top surface 42 of the light-blocking structure 4 is substantially coplanar with the top surfaces 23A, 23B, 23C of the light-transmitting structures 2A, 2B, 2C. Referring to FIG. 17B, the outer side surfaces 22A, 22B, 22C of the light-transmitting structures 2A, 2B, 2C are surrounded and covered by the light-blocking structure 4. A light-emitting unit is wrapped by a light-transmitting structure and the light-transmitting structure has a shape of rectangle, square, triangle, pentagon, hexagon or circle. The light emitted by the adjacent light-emitting unit or the light-transmitting structure is blocked by the light-blocking structure 4 and does not affect each other. In an embodiment, the light-emitting unit is rectangular and wrapped by the light-transmitting structure, and the light-transmitting structure is square from a top view. Or the light-emitting unit is square and wrapped by the light-transmitting structure, and the light-transmitting structure is rectangular.

Referring to FIG. 17A, the light-emitting unit 1A has a pair of conductive electrodes 31A, 31B located on the bottom surface opposite to the top surface 11 of the light-emitting unit 1A. The light-emitting units 1B, 1C also have a pair of conductive electrodes 31B, 32B, and a pair of conductive electrodes 31C, 32C, respectively. The pairs of conductive electrodes 31A, 32A, 31B, 32B, 31C, 32C are electrically connected to an external electrical system. The pairs of conductive electrodes 31A, 32A, 31B, 32B, 31C, 32C may protrude from the light-transmitting structures 2A, 2B, 2C. In other words, the bottom surfaces of the pairs of conductive electrodes 31A, 32A, 31B, 32B, 31C, 32C are not flush with the bottom surfaces of the light-emitting units 1A, 1B, 1C, the light-transmitting structures 2A, 2B, 2C, or the light-blocking structure 4. Referring to the bottom view of FIG. 17C, the light-emitting device 5001 has more than one pair of conductive electrodes 31A, 32A, 31B, 32B, 31C, 32C, and each pair of conductive electrodes are also isolated from each other by the light-blocking structure 4. The light-transmitting structures 2A, 2B, and 2C do not cover the bottom surfaces of the light-emitting units 1A, 1B, and 1C. Therefore, some light may be emitted from the bottom surfaces of the light-emitting units 1A, 1B, and 1C without passing through the light-transmitting structures 2A, 2B, and 2C. In another embodiment, the light-transmitting structure may also cover the bottom surface of the light-emitting unit not covered by the conductive electrode as the above-mentioned light-emitting devices 1002 and 1003, so as to protect the light-emitting unit and avoid light leaked from the bottom part of the light-emitting device.

The light emitted by the light-emitting units 1A, 1B, 1C in the light-emitting device 5001 may have the same or different peak wavelength or dominant wavelength. Each or partial of the light-transmitting structures 2A, 2B, 2C may include a wavelength-converting material (for example, phosphor powder, a dye, or nanoparticle). When the light-transmitting structure includes the wavelength-converting material, all or a part of the light emitted by the corresponding covered light-emitting unit is firstly converted by the wavelength-converting material and then leaves the light-emitting device. When the light-transmitting structure does not include the wavelength-converting material, the light emitted by the corresponding light-emitting unit exits the light-emitting device without wavelength conversion. When a part or all of the light-transmitting structures have wavelength-converting material, the wavelength-converting materials located in different light-transmitting structures may have the same composition therefore the wavelength-converting materials located in different light-transmitting structures have similar excitation and emission spectra. In an embodiment, the different light-transmitting structures have the same composition of wavelength-converting material, but the weight percentage is different with respect to the light-transmitting structure. When a part or all of the light-transmitting structures have wavelength-converting material, the wavelength-converting materials located in different light-transmitting structures have different compositions therefore the wavelength-converting materials located in different light-transmitting structures have different excitation and emission spectra. Therefore, the light emitted by the different light-emitting units is converted into different radiation wavelengths and exits the light-emitting device 5001.

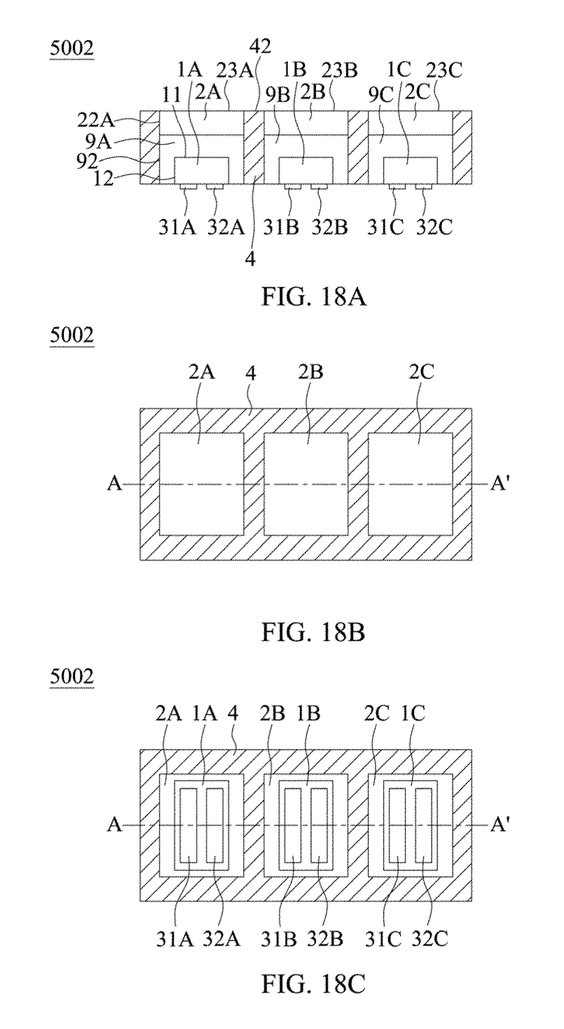

FIG. 18A shows a cross-sectional view of a light-emitting device 5002 in accordance with an embodiment of the present disclosure. FIG. 18B shows a top view of the light-emitting device 5002 in an embodiment of the present disclosure. FIG. 18C shows a bottom view of the light-emitting device 5002 in an embodiment of the present disclosure. FIG. 18A shows a cross-sectional view of the line AA′ in FIG. 18B. The light-emitting device 5002 includes a plurality of light-emitting units 1A, 1B, 1C, a plurality of light-transmitting structures 2A, 2B, 2C separated from each other, optic structures 9A, 9B, 9C, a plurality of pairs of conductive electrodes 31A, 32A, 31B, 32B, 31C, 32C, and a light-blocking structure 4. The optic structures 9A, 9B, and 9C are respectively located between the light-emitting units 1A, 1B, 1C and the light-transmitting structures 2A, 2B, 2C, and cover the top surface 11 and the side surface 12 of the light-emitting units 1A, 1B, 1C. Taking the light-emitting unit 1A as an example, the optic structure 9A covering the light-emitting unit 1A has an outer side surface 92 which is substantially coplanar with the outer side surface 22A of the light-transmitting structure 2A. The optic structure 9A makes a space greater than 0 between the light-transmitting structure 2A and the top surface 11 of the light-emitting unit 1A. The arrangement of the light-emitting units 1B, 1C, the optic structures 9B, 9C, and the light-transmitting structures 2B, 2C are similar to that of the light-emitting unit 1A. The light-blocking structure 4 surrounds the plurality of light-emitting units 1A, 1B, 1C and is located between the light-transmitting structures 2A, 2B, 2C and in contact with the outer side surfaces 22A, 22B, 22C of the light-transmitting structures 2A, 2B, 2C and the outer side surface 92 of the optic structure 9. The top surface 42 of the light-blocking structure 4 is substantially coplanar with the top surfaces 23A, 23B, 23C of the light-transmitting structures 2A, 2B, 2C. Referring to the top view of FIG. 18B, the outer side surfaces 22A, 22B, 22C of the light-transmitting structures 2A, 2B, 2C are surrounded and covered by the light-blocking structure 4. A light-emitting unit is wrapped by the light-transmitting structure and the light-transmitting structure has a shape of rectangle, square, triangle, pentagon, hexagon or circle. The light emitted by the adjacent light-emitting unit or the light emitted by the optic structure and the light-transmitting structure are blocked by the light-blocking structure 4 and does not affect each other. In one embodiment, the optic structures 9A, 9B, 9C do not comprise wavelength-converting material, and the light-transmitting structures 2A, 2B, 2C comprise wavelength-converting material. In another embodiment, the optic structure 9 may comprise diffusion particles or a wavelength-converting material.

Referring to FIG. 18A, the light-emitting unit 1A has a pair of conductive electrodes 31A, 31B located on the bottom surface opposite to the top surface 11 of the light-emitting unit 1A. The light-emitting units 1B, 1C also have a pair of conductive electrodes 31B, 32B, and a pair of conductive electrodes 31C, 32C, respectively. The pairs of conductive electrodes 31A, 32A, 31B, 32B, 31C, 32C are electrically connected to an external electrical system. The pairs of conductive electrodes 31A, 32A, 31B, 32B, 31C, 32C may protrude from the optic structures 9A, 9B, 9C. In other words, the bottom surfaces of the pairs of conductive electrodes 31A, 32A, 31B, 32B, 31C, 32C are not flush with the bottom surfaces of the light-emitting units 1A, 1B, 1C, the optic structures 9A, 9B, 9C, or the light-blocking structure 4. The arrangement and description of the conductive electrodes of the light-emitting device 5002 are similar to the above-mentioned descriptions of the light-emitting device 5001. The characteristics of the light-emitting units 1A, 1B, 1C and the light-transmitting structures 2A, 2B, 2C are similar to the above-mentioned descriptions of the light-emitting device 5001.

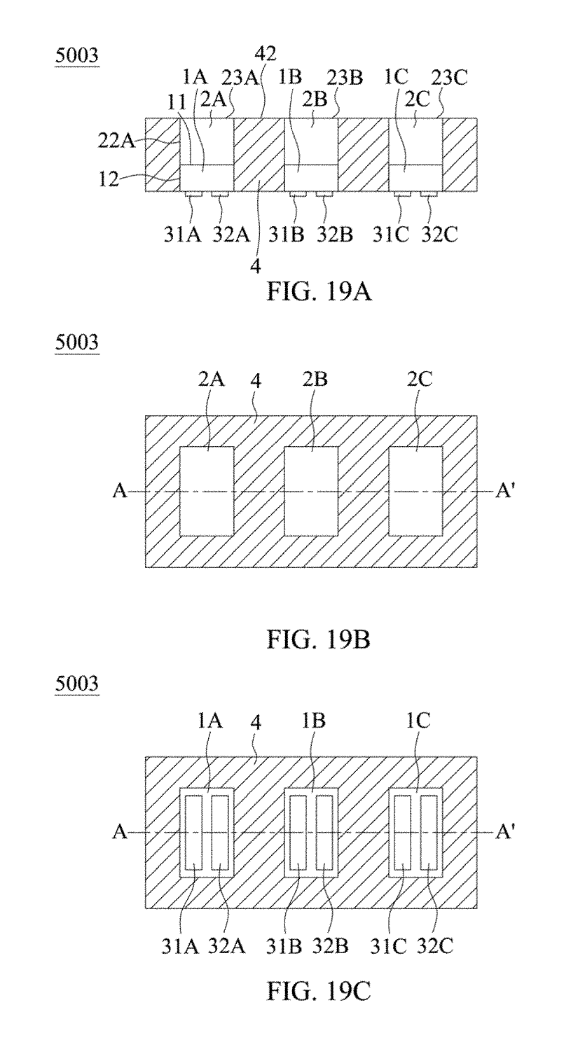

FIG. 19A shows a cross-sectional view of a light-emitting device 5003 in accordance with an embodiment of the present disclosure. FIG. 19B shows a top view of the light-emitting device 5003 in an embodiment of the present disclosure. FIG. 19C shows a bottom view of the light-emitting device 5003 in an embodiment of the present disclosure. FIG. 19A shows a cross-sectional view of the line AA′ in FIG. 19B. The light-emitting device 5003 includes a plurality of light-emitting units 1A, 1B, 1C, a plurality of light-transmitting structures 2A, 2B, 2C separated from each other, a plurality of pairs of conductive electrodes 31A, 32A, 31B, 32B, 31C, 32C, and a light-blocking structure 4. Taking the light-emitting unit 1A as an example, the light-transmitting structure 2A covers the top surface 11 of the light-emitting unit 1A. The outer side surface 22A of the light-transmitting structure 2A is substantially coplanar with the side surface 12 of the light-emitting unit 1A. The arrangement of the light-emitting units 1B, 1C and the light-transmitting structures 2B, 2C are similar to that of the light-emitting unit 1A. The light-blocking structure 4 is located between the light-transmitting structures 2A, 2B, 2C and in contact with the outer side surfaces 22A, 22B, 22C of the light-transmitting structures 2A, 2B, 2C. The top surface 42 of the light-blocking structure 4 is substantially coplanar with the top surfaces 23A, 23B, 23C of the light-transmitting structures 2A, 2B, 2C. Referring to FIG. 19B, the outer side surfaces 22A, 22B, 22C of the light-transmitting structures 2A, 2B, 2C are surrounded and covered by the light-blocking structure 4. A light-emitting unit is wrapped by the light-transmitting structure and the light-transmitting structure has a shape of rectangle, square, triangle, pentagon, hexagon or circle. Therefore, the light emitted by the adjacent light-emitting unit or the light-transmitting structure is blocked by the light-blocking structure 4 and does not affect each other. Compared with the light-emitting devices 5001 and 5002, in the light-emitting element 5003, there is no light-transmitting structure or optic structure between the side surface 12 of the light-emitting unit and the light-blocking structure 4. On the premise that the light-emitting units are the same, the illumination angle of the light-emitting device 5003 is smaller than that of the light-emitting devices 5001 and 5002.

The arrangement and description of the conductive electrodes of the light-emitting device 5003 are similar to the above-mentioned descriptions of the light-emitting devices 5001 and 5002. The characteristics of the light-emitting units 1A, 1B, 1C and the light-transmitting structures 2A, 2B, 2C are similar to the above-mentioned descriptions of the light-emitting devices 5001 and 5002.

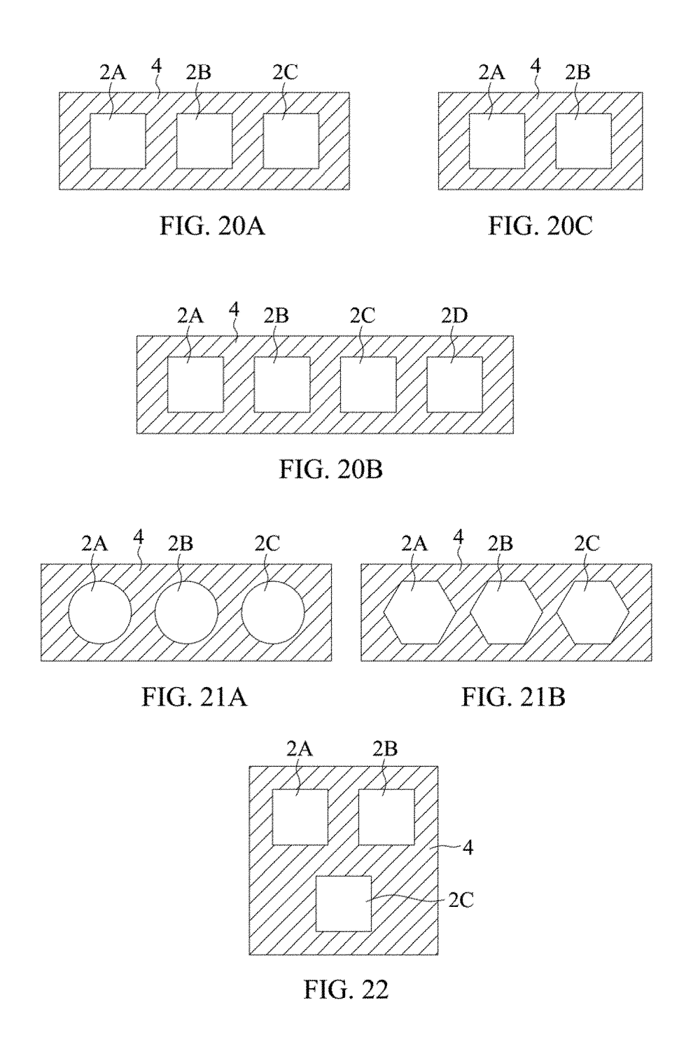

The number of light-emitting units of the above-mentioned light-emitting devices 5001 to 5003 is not limited to three. The number of light-emitting units can be adjusted according to the desired light-emitting characteristics. The light-transmitting structure covering the light-emitting unit can also be added with or without a wavelength-converting material according to the desired light-emitting characteristics. Since the plurality of light-emitting units are located in the same light-emitting device and the conductive electrodes are located at the bottom of the light-emitting device, the light-emitting device including the plurality of light-emitting units can be assembled into the light-emitting module by using Surface-mount technology (SMT) without wire bonding. Moreover, by adding different wavelength-converting materials into the different light-transmitting structures, it is also possible to emit multi-color lights simultaneously in a small-volume light-emitting device. FIGS. 20A to 20C show the top views of embodiments with different number of light-emitting unit and different shape of light-transmitting structure. It should be noted that the cross-sectional views of FIGS. 20A to 20C and the bottom view can be referred to any related drawings of the above-mentioned light-emitting devices 5001 to 5003. FIG. 20A shows the light-emitting device having three light-emitting units. The light-transmitting structure 2A includes red phosphor powder, the light-transmitting structure 2B includes green phosphor powder, and the light-transmitting structure 2C includes blue phosphor powder. The light-transmitting structures are not limited to the arrangement of the above color lights, and any reasonable and possible combination can be used, following the same. FIG. 20B shows the light-emitting device having four light-emitting units. The light-transmitting structure 2A includes red phosphor powder, the light-transmitting structures 2B, 2C include green phosphor powder, and the light-transmitting structure 2D includes blue phosphor powder. In another embodiment, when the light emitted by the light-emitting unit under the light-transmitting structure 2D is blue light (a peak wavelength or a dominant wavelength between 450 to 490 nm), the light-transmitting structure 2D may not have wavelength-converting material. Therefore, FIGS. 20A to 20B are the light-emitting devices having red, blue, green lights, which can be applied to a backlight module of a display, especially for a display with high NTSC/HDR. FIG. 20C shows the light-emitting device having two light-emitting units. The light-transmitting structures 2A and 2B include different phosphor powders. The light-transmitting structures 2A and 2B can emit white lights having different color temperatures, for example, warm white light and cold white light. This light-emitting device can be applied to the flash module having high color rendering, and can properly compensate for white balance. The above-mentioned light-emitting devices capable of emitting different color temperatures or different color combinations are not limited to use in a display or a flash module, and can also be applied to a situational light or a decorative light. Because of its small size and without wire-bonding for assembly, the design of the lighting module can be more flexible. In another embodiment, the light-transmitting structure in FIGS. 20A to 20C can cover one or more light-emitting units.

The above-mentioned light-emitting device including a plurality of light-emitting units has a rectangular shape from the top view, and the shape of the light-transmitting structure and the light-blocking structure 4 have a rectangular shape. In another embodiment, the light-transmitting structure has a shape different from the light-blocking structure from a top view. In other words, the light-transmitting structure has one or more outer sides, and one or more outer sides of the light-transmitting structure are not all parallel to the outer sides of the light-blocking structure, as shown in FIGS. 21A and 21B. The number of the light-transmitting structures is merely an example and does not constitute a limitation of the present disclosure. Referring to FIG. 21A, the light-transmitting structure has a circular outer shape from a top view, which is different from the rectangular shape of the light-blocking structure 4. Referring to FIG. 21B, the light-transmitting structure has a hexagonal shape from a top view, which is different from the rectangular shape of the light-blocking structure 4. In another embodiment, a light-emitting device comprises a plurality of light-transmitting structures, and each of the light-transmitting structures may have a different shape in a top view, or part of the light-transmitting structures are the same and part of the light-transmitting structures are different. The shape of the light-transmitting structure in the top view is not limited to a circular shape or a hexagonal shape, and may be other non-rectangular shapes such as triangle, ellipse, or pentagon. In another embodiment, the shape of the light-emitting unit may be different from the shape of the light-transmitting structure covering the light-emitting unit.

The light-emitting device comprising a plurality of light-emitting units is viewed from top. The light-transmitting structures (and/or light-emitting units) are arranged in a straight line. In other words, the geometric centers of each of the light-transmitting structures are virtually arranged in a straight line. In another embodiment, from the top view, the light-transmitting structures are not arranged in a straight line. In other words, the geometric centers of the light-transmitting structures are not virtually arranged in a straight line. Referring to FIG. 22, the light-transmitting structures are arranged as a triangular shape. In other words, the geometric centers of the respective light-transmitting structures are virtually arranged in a triangle. It should be noted that the shape of each light-transmitting structure in this embodiment does not have to be rectangular, which is merely exemplified herein, and may also be non-rectangular shape as described in the previous paragraphs. Furthermore, the number of the light-transmitting structures in this case is only exemplified, and does not constitute a limitation of the present disclosure. For example, the number of light-transmitting structures is four, and the geometric centers of the respective light-transmitting structures are virtually arranged in a rectangular shape, a parallelogram shape, or a trapezoidal shape.

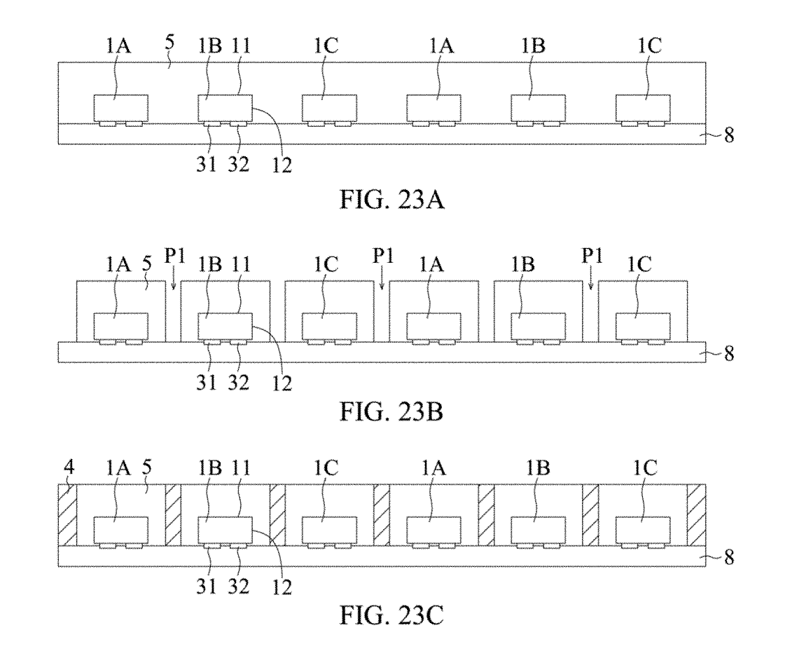

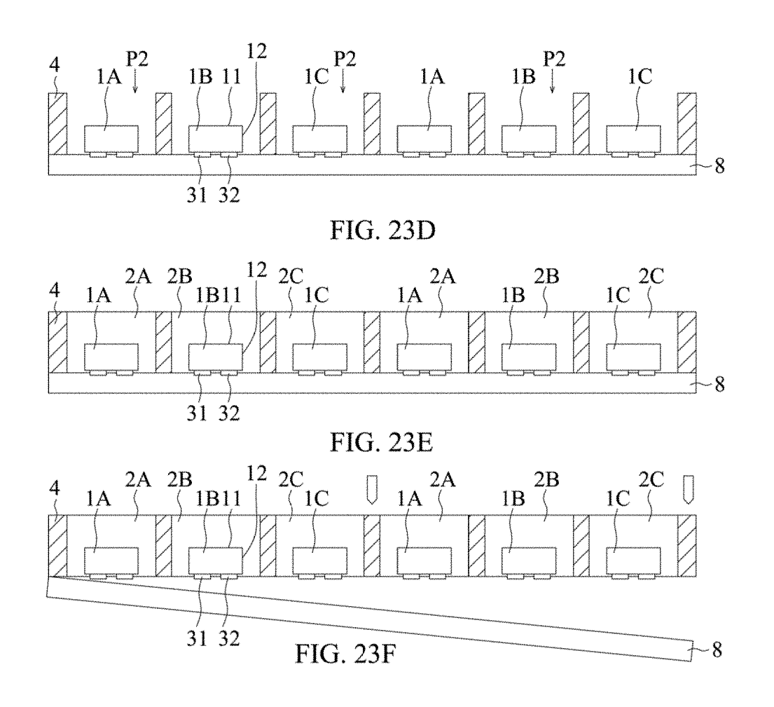

FIGS. 23A to 23F show the manufacturing process of a light-emitting device in accordance with an embodiment of the present disclosure. Referring to FIG. 23A, a temporary carrier 8 having adhesiveness is provided first, and a plurality of light-emitting units 1A, 1B, 1C are placed on the temporary carrier 8. The lower portions of the pair of conductive electrodes 31, 32 are buried in the temporary carrier 8. The area between light-emitting units 1A, 1B, 1C is defined as a path area. Next, a dry film photoresist layer 5 is bonded to the top surface 11 and the side surface 12 of the light-emitting units 1A, 1B, 1C, and the top surface of the temporary carrier 8 not covered by the light-emitting units 1A, 1B, 1C. The bonding process is performed by heating and pressing the dry film photoresist layer 5 through an upper mold (not shown) and a lower mold (not shown) to soften the dry film photoresist layer 5 so as to be tightly bonded to the light-emitting units 1A, 1B, 1C. Moreover, when the upper mold and the lower mold are very close, but the dry film photoresist layer 5 has not contacted the light-emitting units 1A, 1B, 1C, the air between the dry film photoresist layer 5 and the light-emitting units 1A, 1B, 1C can be extracted, and air bubbles between the dry film photoresist layer 5 and the light-emitting units 1A, 1B, 1C can be reduced to increase the bonding force between the dry film photoresist layer 5 and the light-emitting units 1A, 1B, 1C. It should be noted that the dry film photoresist layer 5 may be a multi-layer structure, and the number of layers or the thickness of the layer of may be adjusted to adjust the thickness of the dry film photoresist layer 5, thereby changing the optical characteristics of the light-emitting device.

Referring to FIG. 23B, a patterned photo mask (not shown) covers the dry film photoresist layer 5. The patterned photo mask has a plurality of light-transmitting regions and a plurality of opaque regions. The dry film photoresist layer 5 covering the path area is removed by an exposure step (for example, being irradiated by UV light) to form a plurality of openings P1, and the top surfaces 11 and the side surfaces 12 of the light-emitting units 1A, 1B, 1C are still covered by the dry film photoresist layer 5. It should be noted that the patterns of the masks (such as circular, hexagonal, or square.) can be designed according to the shape of the light-transmitting structure of different light-emitting devices. So that the shape of the dry film photoresist layer 5 covering the top surfaces of the light-emitting units 1A, 1B, 1C can be adjusted by the shape of the light-transmitting structure in the top view. Next, referring to FIG. 23C, the light-blocking structure 4 can be filled into the opening P1 by brushing, dispensing, molding, etc. During this process, a planarization process, such as a polish process, may be performed to planarize the top surface of the light-transmitting structure 2 and the dry film photoresist layer 5. Next, referring to FIG. 23D, the dry film photoresist layer 5 located between the light-blocking structures is removed to expose the top surfaces 11 and side surfaces 12 of the light-emitting units 1A, 1B, 1C, to form a plurality of openings P2. Next, referring to FIG. 23E, the light-transmitting structures 2A, 2B, 2C can be filled into the opening P2 by brushing, dispensing, molding, etc., to cover the top surfaces 11 and side surfaces 12 of the corresponding light-emitting units 1A, 1B, 1C. Finally, referring to FIG. 23F, the light-blocking structure 4 is cutting, and the temporary carrier 8 is removed. The bottom surfaces of the pair of conductive electrodes 31, 32 and the light-transmitting structures 2A, 2B, 2C are exposed and the manufacturing process of the light-emitting device 5001 is completed. The method of removing the temporary carrier 8 can be laser peeling, heating separation, dissolution, etc.

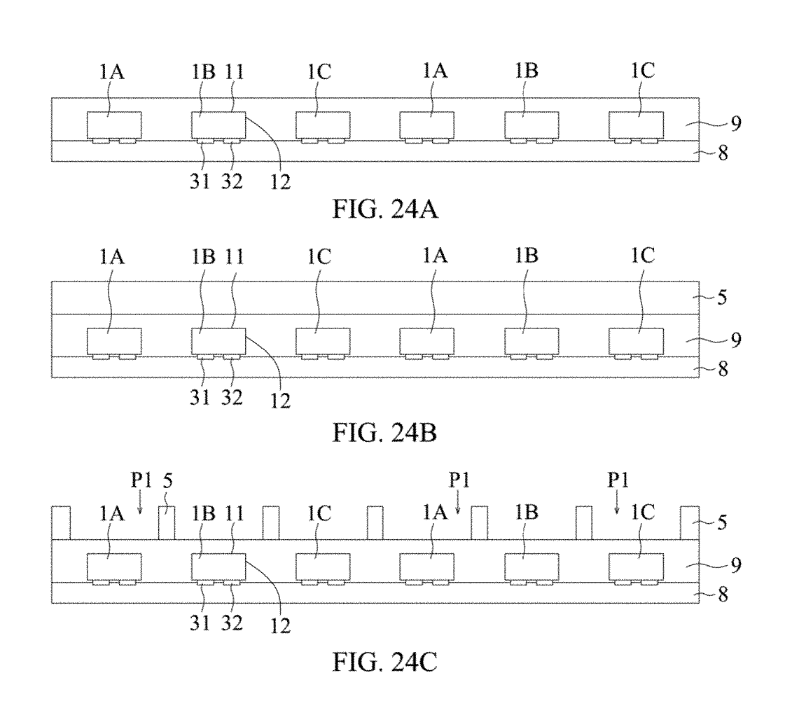

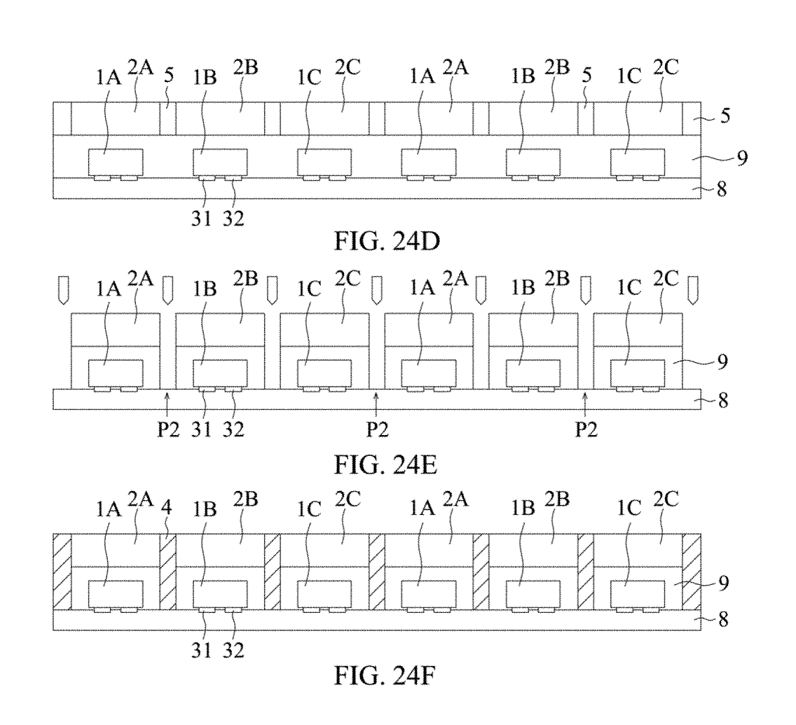

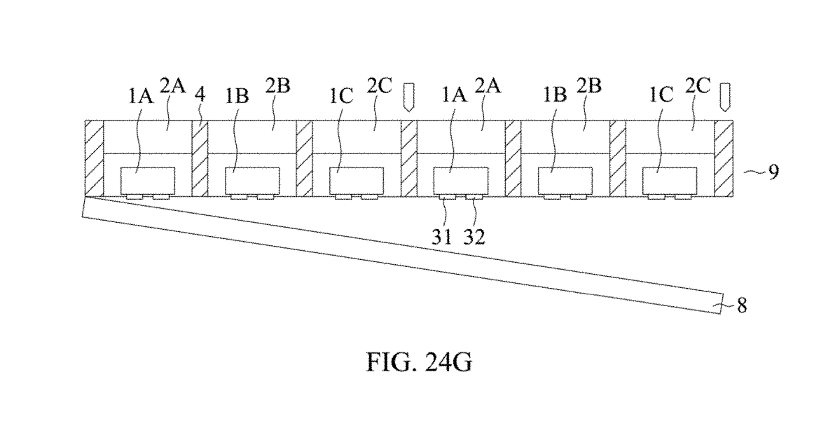

FIGS. 24A to 24G show the manufacturing process of a light-emitting device in accordance with an embodiment of the present disclosure. Referring to FIG. 24A, a temporary carrier 8 having adhesiveness is provided first, and the pair of conductive electrodes 31, 32 of the plurality of light-emitting units 1A, 1B, 1C are placed on the temporary carrier 8. The lower portions of the pair of conductive electrodes 31, 32 are buried in the temporary carrier 8. The area between light-emitting units 1A, 1B, 1C is defined as a path area. Next, an optic structure 9 covers the top surfaces 11 and the side surfaces 12 of the light-emitting units 1A, 1B, 1C and the path area by the method of steel plate printing, coating, brushing, spin coating, ink jet printing, dispensing, etc. During this process, a planarization process, such as a polish process, may be performed to planarize the top surface of the optic structure 9. Next, referring to FIG, 24B, a dry film photoresist layer 5 is bonded over the optic structure 9. It should be noted that the dry film photoresist layer 5 may be a multi-layer structure, and the number of layers or the thickness of the layer may be adjusted to adjust the thickness of the dry film photoresist layer 5, thereby changing the optical characteristics of the light-emitting device. Referring to FIG. 24C, a patterned photo mask (not shown) covers the dry film photoresist layer 5. The patterned photo mask has a plurality of light-transmitting regions and a plurality of opaque regions. The dry film photoresist layer 5 covering the light-emitting units 1A, 1B, 1C is removed by an exposure step (for example, being irradiated by UV light) to form a plurality of openings P1, and the optic structure 9 above the light-emitting units 1A, 1B, 1C is exposed. It should be noted that the masks can have different patterns (such as circular, hexagonal, or square) according to the shape of the light-transmitting structure of different light-emitting devices so that the shape of the dry film photoresist layer 5 covering the top surfaces 11 of the light-emitting units 1A, 1B, 1C can be adjusted by the shape of the light-transmitting structure in the top view.

Referring to FIG. 24D, the light-transmitting structures 2A, 2B, 2C can be filled into the opening P1 by brushing, dispensing, molding, etc., so that the light-transmitting structures 2A, 2B, and 2C respectively cover the corresponding light-emitting unit 1A, 1B, and 1C. Next, referring to FIG. 24E, the dry film photoresist layer 5 located between the light-blocking structures is cut and removed to form a plurality of openings P2. At this time, the optic structure 9 covering the light-emitting units 1A, 1B, 1C is substantially coplanar with the outer side surfaces of the light-transmitting structures 2A, 2B, 2C. Next, referring to FIG. 24F, the light-blocking structure 9 can be filled into the opening P2 by brushing, dispensing, molding, etc. A planarization process, such as a polish process, can also be performed to planarize the top surface of the light-emitting device. Finally, referring to FIG. 24G, the light-blocking structure 4 is cutting, and the temporary carrier 8 is removed. The bottom surfaces of the pair of conductive electrodes 31, 32 and the optic structure 9 are exposed and the manufacturing process of the light-emitting device 5002 is completed. The method of removing the temporary carrier 8 can be laser peeling, heating separation, dissolution, etc.

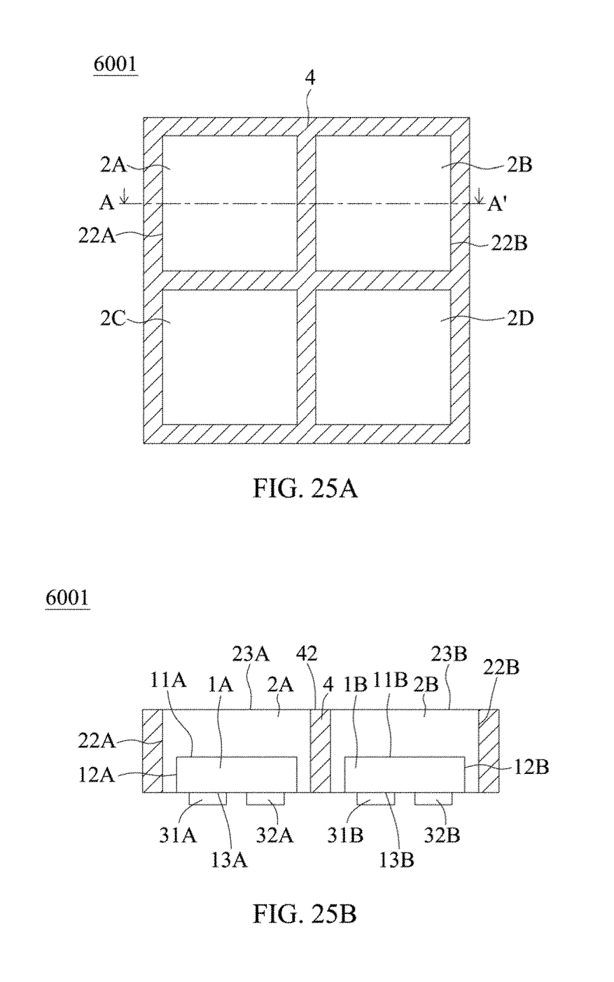

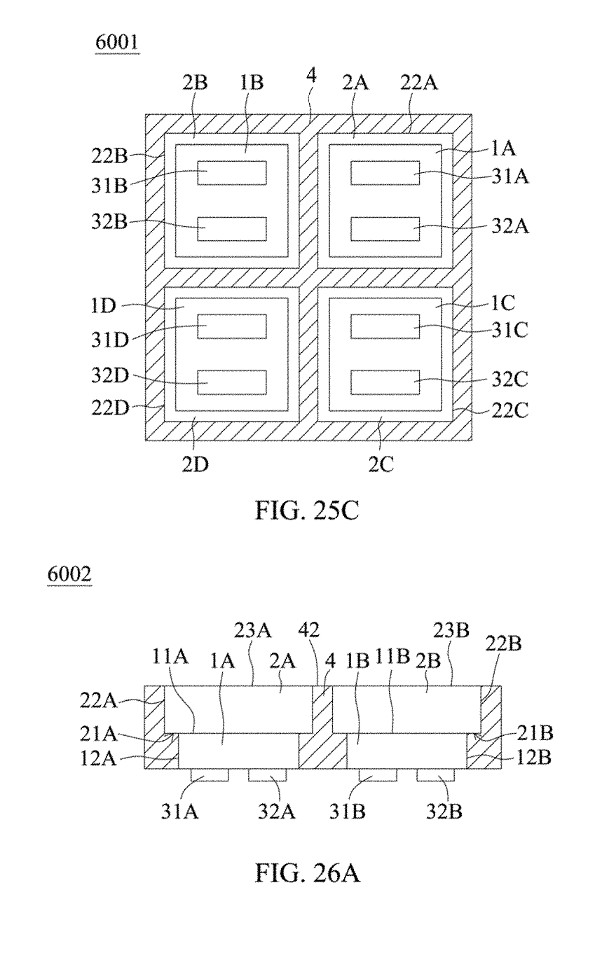

FIGS. 25A to 25C are the diagrams of a light-emitting device in accordance with an embodiment of the present disclosure. FIG. 25A shows a top view of a light-emitting device 6001 in an embodiment of the present disclosure. FIG. 25B shows a cross-sectional view of a light-emitting device 6001 in an embodiment of the present disclosure. FIG. 25C shows a bottom view of the light-emitting device 6001 in an embodiment of the present disclosure. FIG. 25C is a cross-sectional view of the line AA′ in FIG. 25A. The light-emitting device 6001 includes a plurality of light-emitting units 1A, 1B, 1C, 1D, a plurality of light-transmitting structures 2A, 2B, 2C, 2D separated from each other, a plurality of pairs of conductive electrodes 31A and 32A, 31B and 32B, 31C and 32C, 31D and 32D, and a light blocking structure 4. Referring to FIG. 25A, the outer side surfaces 22A, 22B, 22C, 22D of the light-transmitting structures 2A, 2B, 2C, 2D are surrounded and covered by the light-blocking structure 4. From the top view, the light-transmitting structures 2A, 2B, 2C, 2D have a rectangular shape and are arranged in a matrix of 2×2. The light-blocking structure 4 surrounding the light-transmitting structures 2A, 2B, 2C, and 2D has a rectangular shape, so that the shape of the light-blocking structure is similar to that of the light-transmitting structure, and both are rectangular. The top view area of the light-emitting device 6001 is less than 6.25 mm², for example: ≤4.84 mm², ≤1.21 mm². The light emitted by the adjacent light-emitting unit or the light-transmitting structure is blocked by the light-blocking structure 4 and does not affect each other. In other embodiments, the shape of the light-blocking structure and the shape of the light-transmitting structure may also be different. For example, the shape of the light-blocking structure and the light-transmitting structure is a combination of triangle, square, rectangle, polygon (four or more angles, but not including a quadrangle), irregular polygon, ellipse, and circle. The shapes of the light-transmitting structures may be all the same, all different, or partially identical, and the shapes can be those described above.

Referring to FIG. 25B, taking the cross-sectional views of the light-emitting units 1A, 1B and the light-transmitting structures 2A, 2B as an example, the light-transmitting structure 2A directly covers the top surface 11A and the side surface 12A of the light-emitting unit 1A. The light-transmitting structure 2B directly covers the top surface 11B and the side surface 12B of the light-emitting unit 1B. The light-blocking structure 4 surrounds the plurality of light-emitting units 1A, 1B and is located between the light-transmitting structures 2A, 2B and is in contact with the outer side surfaces 22A, 22B of the light light-transmitting structures 2A, 2B. The top surface 42 of the light-blocking structure 4 is substantially coplanar with the top surfaces 23A, 23B of the light-transmitting structures 2A, 2B (for example, the height difference between the uppermost surface of the light-transmitting structure and the uppermost surface of the light-blocking structure is less than 5%˜10% of the overall height of the light-blocking structure). The light-emitting unit 1A has a pair of conductive electrodes 31A, 31B located on the bottom surface 13A of the light-emitting unit 1A opposite to the top surface 11A. The light-emitting unit 1B also has a pair of conductive electrodes 31B, 32B located on the bottom surface 13B. The pairs of conductive electrodes 31A, 32A, 31B, 32B are electrically connected to an external conductive system. The pairs of conductive electrodes 31A, 32A, 31B, 32B may protrude from the light-transmitting structures 2A, 2B. In other words, the bottom surfaces of the pairs of conductive electrodes 31A, 32A, 31B, 32B are not flush with the bottom surfaces of the light-emitting units 1A, 1B, the light-transmitting structures 2A, 2B, or the light-blocking structure 4. The cross-sectional views of the light-emitting devices 1C, 1D and the light-transmitting structures 2C, 2D are same with those of the light-emitting devices 1A, 1B and the light-transmitting structures 2A, 2B, and the description thereof will not be repeated here.

Referring to the bottom view of FIG. 25C, the light-emitting device 6001 has more than one pair of conductive electrodes 31A and 32A, 31B and 32B, 31C and 32C, 31D and 32D, and each pair of conductive electrodes is also isolated from each other through the light-blocking structure 4. The light-blocking structure 4 surrounds the outer side surfaces 22A, 22B, 22C, 22D of the light-transmitting structures 2A, 2B, 2C, 2D. The light-transmitting structures 2A, 2B, 2C, and 2D do not cover the bottom surfaces of the light-emitting units 1A, 1B, 1C, and 1D. Therefore, some light emitted from the light-emitting units 1A, 1B, 1C, and 1D may not pass through the light-transmitting structures 2A, 2B, 2C, 2D and emit from the bottom surface. In another embodiment, the light-transmitting structure may also cover the bottom surface of the light-emitting unit not covered by the conductive electrode as the above-mentioned light-emitting devices 1002 and 1003, so as to protect the light-emitting unit and prevent the light-emitting unit from leaking light from bottom of the light-emitting device.

In an embodiment, the light-transmitting structures 2A, 2B, 2C, and 2D comprise four wavelength-converting materials of different emission spectra/excitation spectra, which can respectively generate cold white light, warm white light, green light, and red light after being illuminated by the light-emitting unit. In an embodiment, the light-transmitting structure 2A includes a red phosphor powder having a wavelength of 630 to 660 nm, for example, a phosphor powder including CASN/SCASN. The light-transmitting structure 2B includes a green phosphor powder having a wavelength of 490 to 510 nm, for example, a phosphor powder including LSN, LuAG or beta-sailon. The light-transmitting structure 2C includes a first mixed powder of yellow-green phosphor powder and red phosphor powder, for example, a phosphor powder including CASN/SCASN and YAG. The blue light emitted by the light-emitting unit can be converted into a warm white light with a color temperature of approximately 2000K˜3000K through the first mixed powder. The light-transmitting structure 2D includes a second mixed powder of yellow-green phosphor powder and red phosphor powder, for example, a phosphor powder including CASN/SCASN and YAG. The blue light emitted by the light-emitting unit can be converted into a cold white light with a color temperature of approximately 5000K˜6000K through the second mixed powder. The arrangement of the above-mentioned phosphor powder is merely an example and does not constitute a limitation of the present disclosure. In other embodiments, the arrangement of the above-mentioned phosphor powder can be arbitrarily exchanged. When the light-emitting units 1A, 1B, 1C, and 1D are simultaneously turned on, the light-emitting device 6001 can emit a full-spectrum white light that is similar with sunlight and has a high color rendering index (CRI). For example, the general color rendering index Ra>80, preferably the general color rendering index Ra>85, and more generally the general color rendering index Ra>90. The color rendering index has 15 test color samples (TCS), respectively R1: Light greyish red, R2: Dark greyish yellow, R3: Strong yellow green, R4: Moderate yellowish green, R5: Light bluish green, R6: Light blue, R7: Light violet, R8: Light reddish purple, R9: Strong red, R10: Strong yellow, R11: Strong green, R12: Strong blue, R13: Light yellowish pink, R14: Moderate olive green, R15: Asian skin color. The general color rendering index Ra is the average of the color rendering index from R1 to R8, with a maximum of 100. A higher general color rendering index light source is used for illumination, which can make the object perform better color rendering after being illuminated. The light-emitting device 6001 having at least red phosphor powder and green phosphor powder can emit full-spectrum white light similar with sunlight, and has a better general color rendering index, and can also take into consideration the color rendering of R13 and R15 related to skin color. Therefore, the light-emitting device is suitable for a flash lamp in a camera or other space in which a portrait is required to be illuminated. The light-emitting device 6001 has a CRI>85 at R13 and R15, more preferably a CRI>90 at R13 and R15.

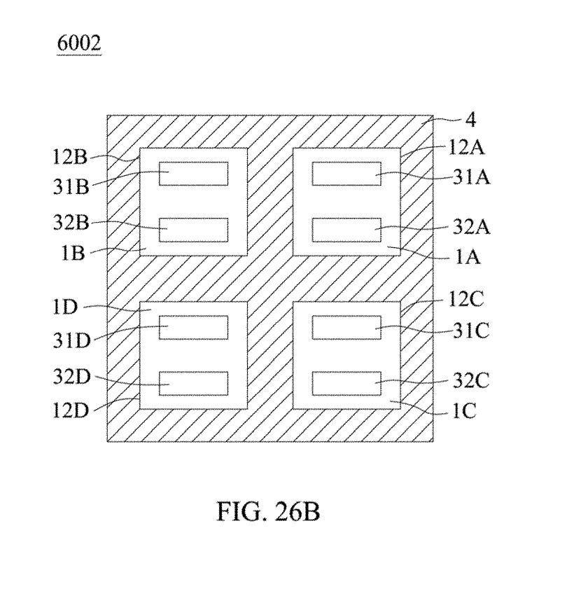

FIGS. 26A to 26B are the diagrams of a light-emitting device 6002 in accordance with another embodiment of the present disclosure. The top view of the light-emitting device 6002 is the same with the light-emitting device 6001 of FIG. 25A, and the structure of the top view can be referred to the above-mentioned paragraph. FIG. 26A shows a cross-sectional view of a light-emitting device 6002 in accordance with an embodiment of the present disclosure. FIG. 26B shows a bottom view of the light-emitting device 6002 in an embodiment of the present disclosure. Taking the cross-sectional views of the light-emitting units 1A, 1B and the light-transmitting structures 2A, 2B as an example, the light-transmitting structure 2A covers the top surface 11A of the light-emitting unit 1A, and the light-transmitting structure 2B covers the top surface 11B of the light-emitting unit 1B. The light-blocking structure 4 surrounds the plurality of light-emitting units 1A, 1B and the light-transmitting structures 2A, 2B, and is in contact with the side surfaces 12 of the light-emitting units 1A, 1B and the outer side surfaces 22A, 22B of the light-transmitting structures 2A, 2B. The outer side surface 22A of the light-transmitting structure 2A is not coplanar with the side surface 12A of the light-emitting unit 1A, and is beyond the side surface 12A of the light-emitting unit 1A. Therefore, a portion of the bottom surface 21A of the light-transmitting structure 2A is covered by the light-blocking structure 4. The outer side surface 22B of the light-transmitting structure 2B is not coplanar with the side surface 12B of the light-emitting unit 1B, and is beyond the side surface 12B of the light-emitting unit 1B. Therefore, a portion of the bottom surface 21B of the light-transmitting structure 2B is covered by the light-blocking structure 4. In other words, the maximum width of the light-transmitting structure 2A is larger than the maximum width of the light-emitting unit 1A, and the maximum width of the light-transmitting structure 2B is larger than the maximum width of the light-emitting unit 1B. The top surface 42 of the light-blocking structure 4 is substantially coplanar with the top surfaces 23A, 23B of the light-transmitting structures 2A, 2B. The light-emitting unit 1A has a pair of conductive electrodes 31A, 31B located on the bottom surface opposite to the top surface 11A of the light-emitting unit 1A. The light-emitting unit 1B also has a pair of conductive electrodes 31B, 32B on the bottom surface. The pairs of conductive electrodes 31A, 32A, 31B, 32B are electrically connected to an external conductive system. The pairs of conductive electrodes 31A, 32A, 31B, 32B may protrude from the light-blocking structure 4. In other words, the bottom surfaces of the pairs of conductive electrodes 31A, 32A, 31B, 32B are not flush with the bottom surfaces of the light-emitting units 1A, 1B, or the bottom surface of the light-blocking structure 4. The cross-sectional views of the light-emitting devices 1C and 1D and the light-transmitting units 2C and 2D are the same as those of the light-emitting devices 1A and 1B and the light-transmitting units 2A and 2B, and the description thereof will not be repeated here.

Referring to the bottom view of FIG. 26B, the light-emitting device 6002 has more than one pair of conductive electrodes 31A and 32A, 31B and 32B, 31C and 32C, 31D and 32D, and each pair of conductive electrodes is also isolated from each other through the light-blocking structure 4. The light-blocking structure 4 does not cover the bottom surfaces of the light-emitting units 1A, 1B, 1C, and 1D. Therefore, some light emitted from the light-emitting units 1A, 1B, 1C, and 1D may emit from the bottom surface. In another embodiment, the light-blocking structure 4 may also cover the bottom surface of the light-emitting unit not covered by the conductive electrode, so as to protect the light-emitting unit and prevent the light-emitting unit from leaking light from bottom of the light-emitting device.

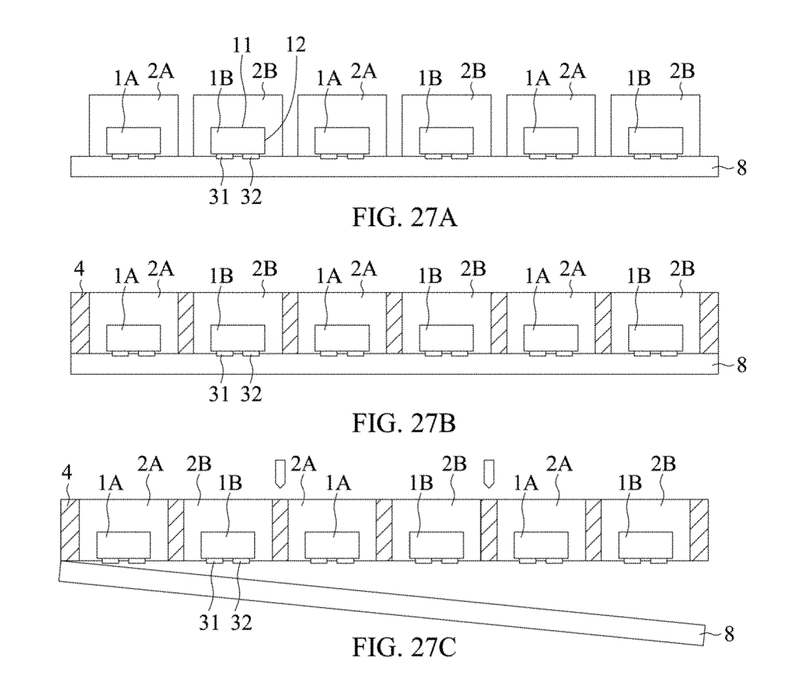

FIGS. 27A to 27C are the diagrams showing the manufacturing process of the light-emitting device 6001 in accordance with an embodiment of the present disclosure. This schematic view only shows the structure in line AA′ of FIG. 25A, but other parts not shown are also suitable for the same manufacturing process. Referring to FIG. 27A, the structure in which the light-transmitting structure 2A covers the top surface and the side surface of the light-emitting unit 1A, the structure in which the light-transmitting structure 2B covers the top surface and the side surface of the light-emitting unit 1B, the structure in which the light-transmitting structure 2C covers the top surface and the side surface of the light-emitting unit 1C (not shown), and the structure in which the light-transmitting structure 2D covers the top surface and the side surface of the light-emitting unit 1D (not shown) are initially formed. A temporary carrier 8 having adhesiveness is provided, and the light-emitting units 1A, 1B, 1C, and 1D separated from each other and covered by the light-transmitting structure are disposed on the temporary carrier 8. The lower portions of the pair of conductive electrodes 31 and 32 are buried into the temporary carrier 8. The area between the adjacent light-transmitting structures is defined as the path area. The light-transmitting structure covers the top surface and the side surface of the light-emitting unit by steel plate printing, coating, brushing, spin coating, ink jet printing, dispensing, molding, etc. Next, referring to FIG. 27B, the light-blocking structure 4 is filled into the path area by brushing, dispensing, molding, etc. A planarization process, such as a polish process, may be performed to planarize the top surface of the light-blocking structure 4. Subsequently, referring to FIG. 27C, the cutting and removing of the temporary carrier 8 are performed, and the conductive electrode, the light-blocking structure, and the bottom surface of the light-transmitting structure are exposed to complete the manufacture of the light-emitting device.

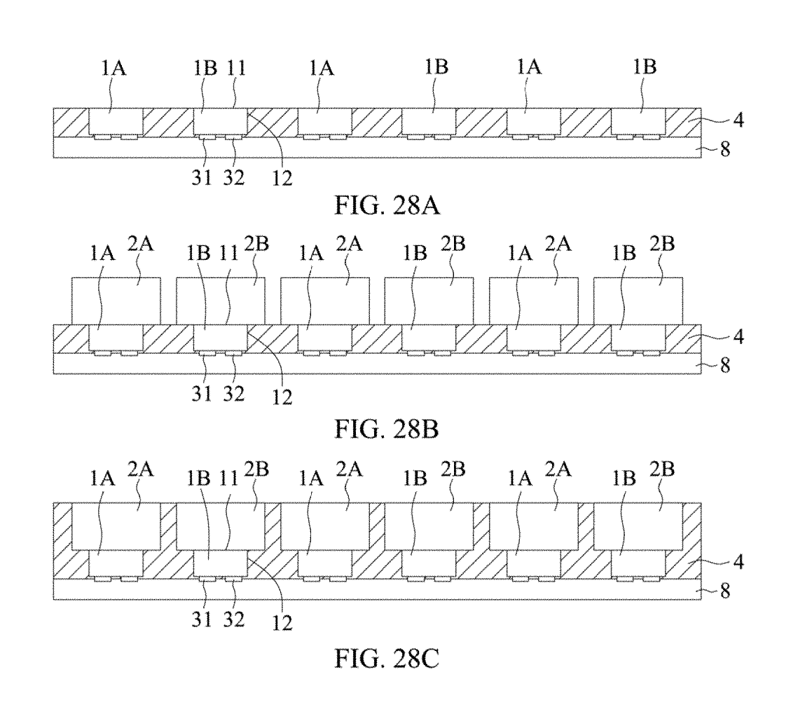

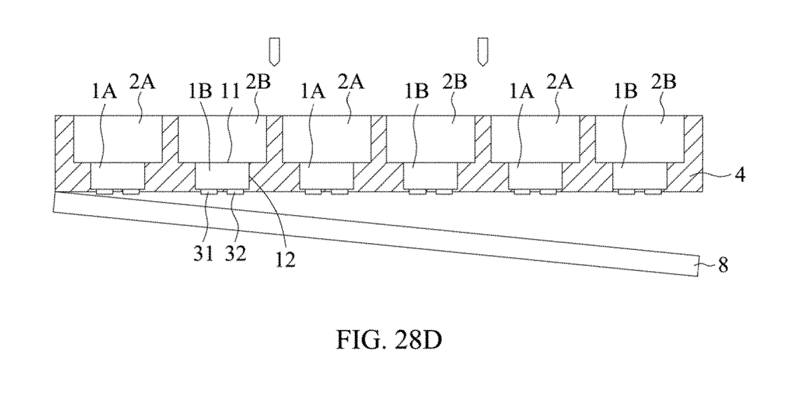

FIGS. 28A to 28D are the diagrams showing the manufacturing process of the light-emitting device 6002 in accordance with an embodiment of the present disclosure. This schematic view only shows the structure in line AA′ of FIG. 25A, but other parts not shown are also suitable for the same manufacturing process. Referring to FIG. 28A, a temporary carrier 8 having adhesiveness is provided first, and the pair of conductive electrodes 31, 32 of a plurality of light-emitting units 1A, 1B, 1C, 1D are disposed on the temporary carrier 8. The lower portions of the pair of conductive electrodes 31, 32 are buried into the temporary carrier 8. The area between adjacent light-emitting units 1 is defined as a path area. Next, the light-blocking structure 4 can be filled into the path area by steel plate printing, coating, brushing, spin coating, ink jet printing, dispensing, molding, etc. A planarization process, such as a polish process, may be performed to planarize the top surface of the light-blocking structure 4 and expose the top surfaces of the light-emitting units 1A, 1B, 1C, 1D. Next, referring to FIG. 28B, the light-transmitting structures 2A, 2B, 2C, and 2D separated from each other are bonded to the light-emitting units 1A, 1B, 1C, and 1D. The light-transmitting structures 2A, 2B, 2C, 2D are separated from each other and have a path with a distance greater than zero between each other. Subsequently, referring to FIG. 28C, the light-blocking structure 4 is filled into the path between the light-transmitting structures 2A, 2B, 2C, 2D. A planarization process can be performed to planarize the top surfaces of the light-blocking structure 4 and the light-transmitting structure. Next, referring to FIG. 28D, the cutting and removing of the temporary carrier 8 are performed, and the bottom surfaces of the conductive electrode and the light-blocking structure are exposed to complete the fabrication of the light-emitting device.

It should be understood that the various embodiments described above may be combined or substituted with each other as appropriate, and are not limited to the specific embodiments described. The examples of the disclosure are only intended to be illustrated and not to limit the scope of the disclosure. Any obvious modifications or variations of the present disclosure will occur without departing from the spirit and scope of the present disclosure.

What is claimed is:

1. A light-emitting device, comprising:
a first light-emitting unit having a first top surface, a first side surface and a first bottom surface;
a second light-emitting unit having a second top surface, a second side surface and
a second bottom surface;
a first pair of conductive electrodes disposed on the first bottom surface;
a second pair of conductive electrodes disposed on the second bottom surface;
a first optic structure having a first outer side surface and covering the first top surface and the first side surface;
a second optic structure having a second outer side surface and covering the second top surface and the second side surface;
a first light-transmitting structure having a third outer side surface and covering the first optic structure;
a second light-transmitting structure having a fourth outer side surface and covering the second optic structure; and
a light-blocking structure surrounding the first light-emitting unit and the second light-emitting unit, the light-blocking structure covering the first outer side surface,
the second outer side surface, the third outer side surface and the fourth outer side surface.

2. The light-emitting device of claim 1, wherein the first outer side surface is substantially coplanar with the third outer side surface.

3. The light-emitting device of claim 1, wherein the light-blocking structure is in direct contact with the first outer side surface and the third outer side surface.

4. The light-emitting device of claim 1, wherein the first light-transmitting structure includes a first wavelength-converting material, the second light-transmitting structure includes a second wavelength-converting material different from the first wavelength-converting material.

5. The light-emitting device of claim 1, wherein the first optic structure and the second optic structure do not include wavelength-converting material.

6. The light-emitting device of claim 1, wherein the shape of the first light-emitting unit is different from the shape of the first light-transmitting structure in a top view.

7. The light-emitting device of claim 1, wherein the shape of the first light-transmitting structure is different from the shape of the light-blocking structure in a top view.

8. The light-emitting device of claim 1, wherein the first pair of conductive electrodes includes a second bottom surface and the second bottom surface is not flush with the first light-transmitting structure.

9. The light-emitting device of claim 1, wherein the first pair of conductive electrodes includes a second bottom surface and the second bottom surface is not flush with the light-blocking structure.

10. The light-emitting device of claim 1, wherein the light-blocking structure includes an outermost side not parallel with the third outer side surface.

11. The light-emitting device of claim 1, wherein the first light-transmitting structure has a third top surface, the second light-transmitting structure has a fourth top surface, the light-blocking structure has a fifth top surface, and the third top surface is substantially coplanar with the fifth top surface.

12. The light-emitting device of claim 11, wherein the fourth top surface is substantially coplanar with the fifth top surface.

13. The light-emitting device of claim 1, wherein the first optic structure has a third bottom surface, the second optic structure has a fourth bottom surface, the light-blocking structure has a fifth bottom surface, and the third bottom surface is substantially coplanar with the fifth bottom surface.

14. The light-emitting device of claim 13, wherein the fourth bottom surface is substantially coplanar with the fifth bottom surface.

15. The light-emitting device of claim 14, wherein the first bottom surface is substantially coplanar with the third bottom surface and the second bottom surface is substantially coplanar with the fourth bottom surface.

16. The light-emitting device of claim 7, wherein the shape of the light-blocking structure is rectangular and the shape of the light-transmitting structure is non-rectangular.

17. The light-emitting device of claim 16, wherein the shape of the light-transmitting structure is circular, hexagonal, triangle, ellipse or pentagon.

18. The light-emitting device of claim 1, further comprising a third light-emitting unit having a sixth top surface and a third side surface, a third optic structure having a fifth outer side surface and covering the six top surface and the third side surface, a third light-transmitting structure having a sixth outer side surface and covering the third optic structure.

19. The light-emitting device of claim 18, wherein the light-blocking structure surrounds the third light-emitting unit and covers the fifth outer side surface and the sixth outer side surface.

20. The light-emitting device of claim 18, wherein the third light-transmitting structure includes a third wavelength-converting material different from the first wavelength-converting material and the second wavelength-converting material.
